(19) United States
(12) Patent Application Publication
(10) Pub. No.: US 2023/0341986 A1
(43) Pub. Date: Oct. 26, 2023

(54) SYSTEMS AND METHODS FOR FORMING WRAP AROUND ELECTRODES

(71) Applicant: CORNING INCORPORATED, CORNING, NY (US)

(72) Inventors: Ya-Huei Chang, Zhudong Township (TW); Daniel Wayne Levesque, JR., Avoca, NY (US); Jen-Chieh Lin, San Jose, CA (US); Lu Zhang, Painted Post, NY (US)

(21) Appl. No.: 17/763,353

(22) PCT Filed: Sep. 23, 2020
(86) PCT No.: PCT/US2020/052132

§ 371 Date: Mar. 24, 2022

Related U.S. Application Data
(60) Provisional application No. 62/913,369, filed on Oct. 10, 2019.

(51) Int. Cl. G06F 3/044; G06F 3/041

(52) U.S. Cl. CPC G06F 3/0448; G06F 3/0446; G06F 3/0412; G06F 2203/04103

(57) ABSTRACT

Embodiments are related generally to display devices, and more particularly to displays or display tiles having electrodes that extend from a first surface to a second surface of a substrate.

### CROSS-REFERENCE TO RELATED APPLICATION

This application claims the benefit of priority under 35 U.S.C. § 119 of U.S. Provisional Application Ser. No. 62/913,369 filed on Oct. 10, 2019, the content of which is relied upon and incorporated herein by reference in its entirety.

### FIELD

Embodiments are related generally to display devices, and more particularly to displays or display tiles having electrodes that extend from a first surface to a second surface of a substrate.

### BACKGROUND

Multiple individual display tiles can be combined into a single large display, sometimes referred to as a tiled display. For example, video walls comprised of multiple display tiles are known for their high-impact engagement and stunning visuals, and are utilized in a variety of settings, including retail environments, control rooms, airports, television studios, auditoriums and stadiums.

The design of display tiles impacts the resolution and performance of the tiled display. FIG. 1 shows a prior art display tile 50 that can be combined with other display tiles to form a tiled display. Display tile 50 includes a first substrate 52 having a first surface 55 and an outer perimeter 56. The display tile 50 includes rows 60 of pixel elements and columns 70 of pixel elements 58. Each row 60 of pixel elements 58 is connected by a row electrode 62 and a plurality of columns 70 of pixel elements 58, and each column 70 of pixel elements 58 is connected by a column electrode 72. Display tile 50 further includes at least one row driver 65 that activates the rows 60 of pixel elements 58 and at least one column driver 75 that activates the columns 70 of pixel elements 58. In the prior art display tile 50, the row drivers 65 and the column drivers 75 are located on the first surface 55 on the same side of the pixel elements, requiring a bezel (not shown) to cover the row drivers 65 and the column drivers 75.

For aesthetic reasons, flat panel display makers are trying to maximize the image viewing area and provide a more aesthetically pleasing appearance by minimizing the size of the bezel surrounding the image on the display. However, there are practical limits to this minimization, and current bezel sizes are on the order of 3 millimeters to 10 millimeters in width.

There have been efforts in the industry to achieve tiled displays comprised of display tiles with little or no bezel. Bezel-free display tiles allow for vast configurations of tiled displays without the need for irritating black gaps. To achieve a bezel-free display tile, it can be advantageous to have the pixel elements in close proximity to the edges of the display tiles. These pixel elements can be located on the front side of the display tile substrate and the control electronics on the back side. As a result, there is a need to electrically interconnect the front and back sides of the display tile substrate.

One way to achieve such interconnects in a display tile substrate made from glass is with metalized through glass vias (“TGVs”). Such TGVs can be used to manufacture a zero bezel microLED display, however, TGVs are fairly expensive to make, at least using current methods which involve laser damage of each hole (a serial process) followed by etch. The vias then need to be further processed for metallization.

Implementation of TGVs presents challenges with overall manufacturing process sequence. If the front of the tile substrate is to have a thin film transistor (TFT) array, a question arises as to when the glass vias are made and metalized. Since TFT array fabrication is traditionally done on a pristine glass surface, etching and metallization may best be done after TFT fabrication. As a result, the array must be protected from etch and also be compatible with the metallization technique. In addition, for TGV first, Cu might be diffused to TFT device and degrade device performance.

Hence, for at least the aforementioned reasons, there exists a need in the art for advanced systems and methods for manufacturing multi-tile displays.

### SUMMARY

Embodiments are related generally to display devices, and more particularly to displays or display tiles having electrodes that extend from a first surface to a second surface of a substrate.

This summary provides only a general outline of some embodiments. The phrases “in one embodiment,” “according to one embodiment,” “in various embodiments”, “in one or more embodiments”, “in particular embodiments” and the like generally mean the particular feature, structure, or characteristic following the phrase is included in at least one embodiment, and may be included in more than one embodiment. Importantly, such phrases do not necessarily refer to the same embodiment. Many other embodiments will become more fully apparent from the following detailed description, the appended claims and the accompanying drawings.

### BRIEF DESCRIPTION OF THE FIGURES

A further understanding of the various embodiments described herein may be realized by reference to the figures which are described in remaining portions of the specification. In the figures, like reference numerals are used throughout several figures to refer to similar components. In some instances, a sub-label consisting of a lower case letter is associated with a reference numeral to denote one of multiple similar components. When reference is made to a reference numeral without specification to an existing sub-label, it is intended to refer to all such multiple similar components.

FIG. 1 is a schematic top perspective view of a prior art display;

FIG. 2 is a schematic top perspective view of a display tile including pixel elements on a one surface of the display tile connected using side electrodes to one or more column/row driver circuits on an opposite surface of the display tile connected by wrap around electrodes in accordance with some embodiments;

FIG. 3 is a side perspective view of the display tile of FIG. 2;

FIG. 4 is a schematic bottom perspective view of the display tile of FIG. 2;

FIGS. 5a-5c show detailed views of wrap around edge electrodes in accordance with some embodiments;

FIG. 6 is top perspective view of a display including a number of display tiles spaced a sufficient distance from one another to accommodate side electrodes on respective display tiles;

FIG. 7 is a flow diagram showing a method in accordance with some embodiments for forming wrap-around, edge electrodes using a laser removal process;

FIGS. 8a-8g show a display tile at various stages of the processing FIG. 7;

FIG. 9 is a flow diagram showing a method in accordance with some embodiments for forming wrap-around, edge electrodes using a laser removal process and a material additive process;

FIGS. 10a-10h show a display tile at various stages of the processing FIG. 9;

FIGS. 11a-11b show plating baths with display tiles disposed within in either a vertical or horizontal orientation;

FIG. 12 is a flow diagram showing another method in accordance with other embodiments for forming wrap-around, edge electrodes using a laser removal process and a material additive process;

FIGS. 13a-13j show a display tile at various stages of the processing FIG. 12.

FIG. 14 is a flow diagram showing yet another method in accordance with other embodiments for forming wrap-around, edge electrodes using a laser removal process and a material additive process; and

FIGS. 15a-15d show a display tile at various stages of the processing FIG. 14.

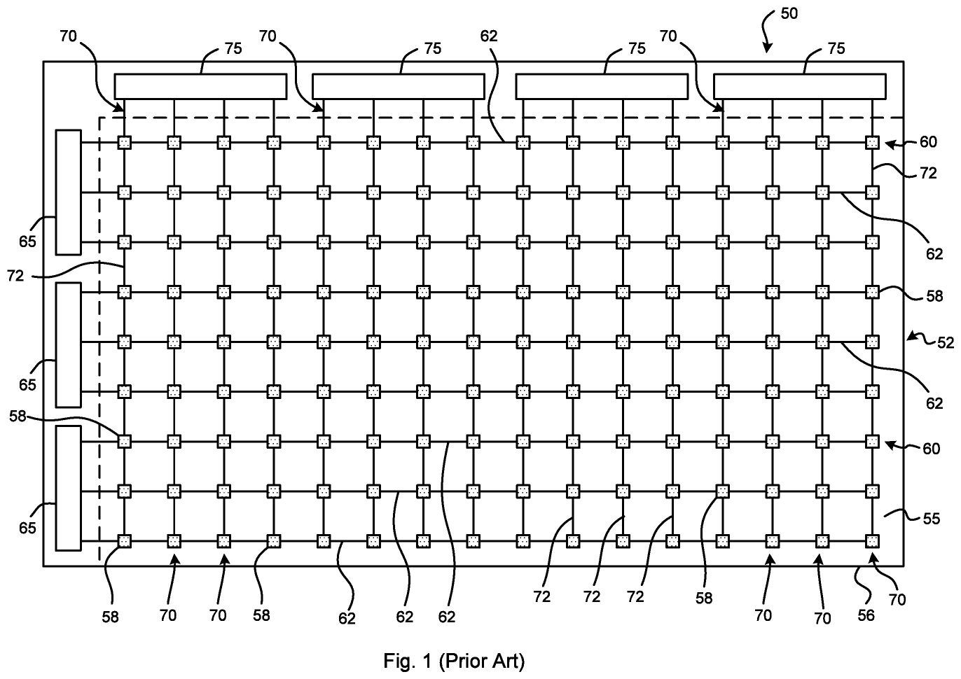

### DETAILED DESCRIPTION

Embodiments are related generally to display devices, and more particularly to displays or display tiles having electrodes that extend from a first surface to a second surface of a substrate.

Various embodiments provide methods for manufacturing displays that are formed of a number of display tiles. Each of the display tiles includes electrodes that wrap around and edge of the display tile and electrically connect circuitry on one side of the display tile with electrical circuitry on another side of the display tile. Formation of the electrodes include laser removal of material formed on a substrate of the display tile.

Other embodiments provide display tiles that include a substrate and an electrode. The substrate includes: a first surface and a second surface, and a side extending between the first surface and the second surface along a portion of an outer perimeter of the substrate. The electrode extends from a first contact location on the first surface of the substrate around the side to a second contact location on the second surface. A cross-sectional width of the electrode measured perpendicular to the electrode and parallel to the first surface is less than or equal to two hundred micrometers, and a minimum thickness of the electrode measured perpendicular to the first surface from the first surface to an opposite surface of the electrode is greater than or equal to two hundred nanometers. In some cases, the minimum thickness of the electrode measured perpendicular to the first surface from the first surface to the opposite surface of the electrode is greater than or equal to five micrometers. In various cases, the minimum thickness of the electrode measured perpendicular to the first surface from the first surface to the opposite surface of the electrode is greater than or equal to eight micrometers

In some instances of the aforementioned embodiments, the display tile further includes: a circuit disposed on or near the second surface, and an electrical element disposed on or near the first surface. The electrode electrically connects the circuit with the electrical element. In some cases, the circuit is a row driver, and the electrical element is a pixel element. In various cases, the pixel element is an LED, a microLED, an LCD display element, an OLED display element, a complementary metal-oxide-semiconductor (CMOS) element, or transistor element.

In various instances of the aforementioned embodiments, the substrate is a glass-based substrate. In some instances of the aforementioned embodiments, a thickness of the side measured as a distance along a line perpendicular to the first surface and extending between the first surface and the second surface is less than or equal to three millimeters. In some instances of the aforementioned embodiments, the electrode is formed of pure metal. In some embodiments, the metal deposition includes sputtering pure copper (Cu), silver (Ag), gold (Au), nickel (Ni), or their combinations. In other cases, the pure metal is a dual layer structure, such as Ti/Cu, TiW/Cu, TiN/Cu, Cr/Cu, where Ti, TiW, TiN or Cr is adhesion layer between pure metal and substrate.

Yet other embodiments provide methods for manufacturing a multi-substrate device. The methods include: depositing a conductive material over at least a first surface of a substrate, a second surface of the substrate, and a side surface of the substrate extending between the first surface and the second surface along a portion of an outer perimeter of the substrate; and laser removing a portion of the conductive material extending from the first surface of the substrate around the side to the second surface leaving a plurality of electrodes formed of the conductive material electrically connecting a first contact location on the first surface to a second contact location on the second surface.

In some instances of the aforementioned embodiments, a cross-sectional width of the electrode measured perpendicular to the electrode and parallel to the first surface is less than or equal to two hundred micrometers, and a minimum thickness of the electrode measured perpendicular to the first surface from the first surface to an opposite surface of the electrode is less than or equal to two hundred nanometers. In various instances of the aforementioned embodiments, the methods further include: forming a circuit on or near the second surface, and connecting an electrical element on or near the first surface. The electrode electrically connects the circuit with the electrical element. In some cases, the circuit is a row driver, and the electrical element is a pixel element. In various cases, the pixel element is an LED, a microLED, an LCD display element, or an OLED display element.

In various instances of the aforementioned embodiments, the methods further include plating the electrode with a plating material such that the minimum thickness of the electrode measured perpendicular to the first surface from the first surface to the opposite surface of the electrode is greater than or equal to three micrometers. Such plating may be either electroplating, electroless plating, or a combination of electroless plating and electroplating. In some cases, the minimum thickness of the electrode measured perpendicular to the first surface from the first surface to the opposite surface of the electrode is greater than or equal to five micrometers. In various cases, the minimum thickness of the electrode measured perpendicular to the first surface from the first surface to the opposite surface of the electrode is greater than or equal to eight micrometers. In some instances of the aforementioned embodiments, the substrate is a glass-based substrate such as, for example, glass or glass-ceramic. In other cases, the substrate is a ceramic, sapphire, silicon, polymer, or print circuit board (PCB)-based substrate. In various instances of the aforementioned embodiments, the plating material is pure metal In some embodiments, the metal deposition includes sputtering pure copper (Cu), silver (Ag), gold (Au), nickel (Ni), or their combinations. In other cases, the pure metal is a dual layer structure, such as Ti/Cu, TiW/Cu, TiN/Cu, Cr/Cu, where Ti, TiW, TiN or Cr is adhesion layer between pure metal and substrate.

Yet further embodiments provide methods for manufacturing a multi-substrate device. The methods include: forming a conductive material over at least a part of a first surface of a substrate, a second surface of the substrate, and a side surface of the substrate extending between the first surface and the second surface along a portion of an outer perimeter of the substrate; forming a protective layer over at least part of each of the first surface, the second surface, and the side; laser removing a portion of the protective layer corresponding to open area between a plurality of electrodes; and etching to remove the conductive material from the area exposed by the laser removing to leave the plurality of electrodes such that each of the plurality of electrodes extends from a first contact location on the first surface of the substrate around the side to a second contact location on the second surface.

In some instances of the aforementioned embodiments, forming the conductive material over at least the part of the first surface of a substrate, the second surface of the substrate, and the side surface of the substrate includes a combination of metal sputtering and metal plating. In some cases, metal plating is electroplating, electroless plating, or a combination of electroless plating and electroplating.

Yet additional embodiments provide methods for manufacturing a multi-substrate device. The methods include: forming a protective layer over at least a part of a first surface of a substrate, a second surface of the substrate, and a side surface of the substrate extending between the first surface and the second surface along a portion of an outer perimeter of the substrate; laser removing a portion of the protective layer corresponding to open area between a plurality of electrodes; forming a conductive material over at least a subset of the part of the first surface of the substrate, the second surface of the substrate, and the side surface of the substrate; and removing the protective to leave a plurality of electrodes formed of the conductive material. Each of the plurality of electrodes extends from a first contact location on the first surface of the substrate around the side to a second contact location on the second surface.

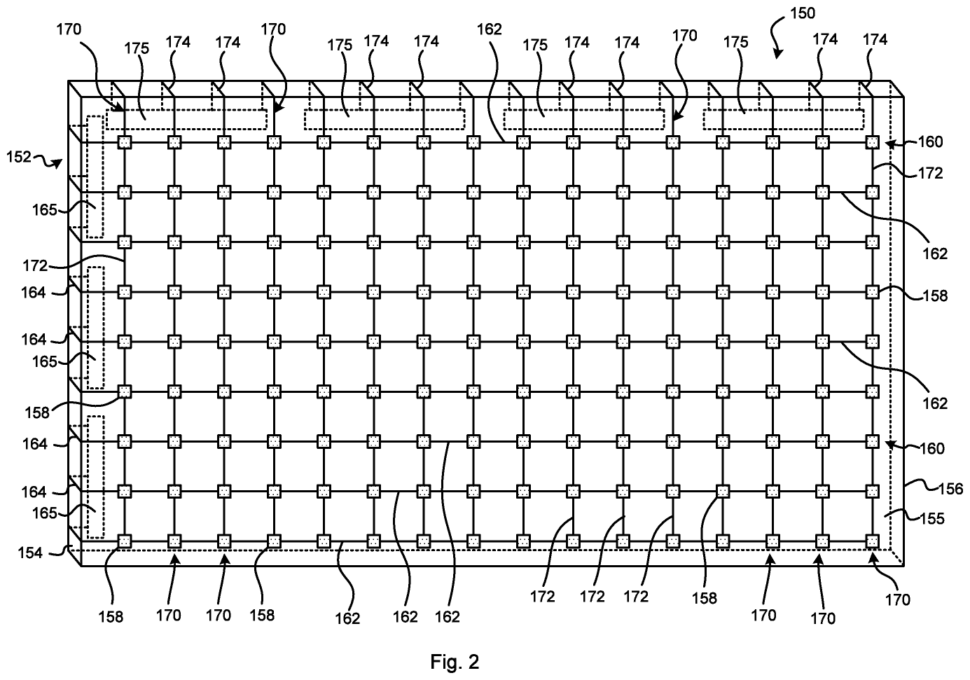

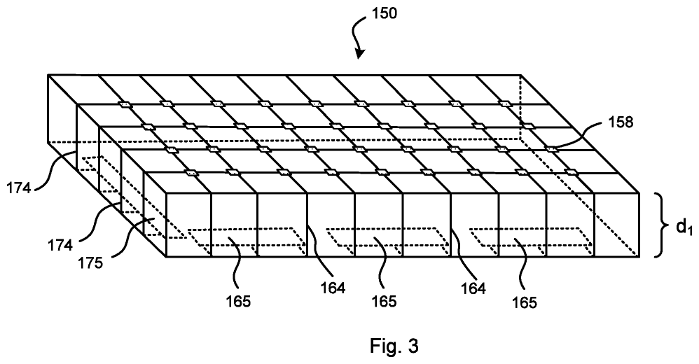

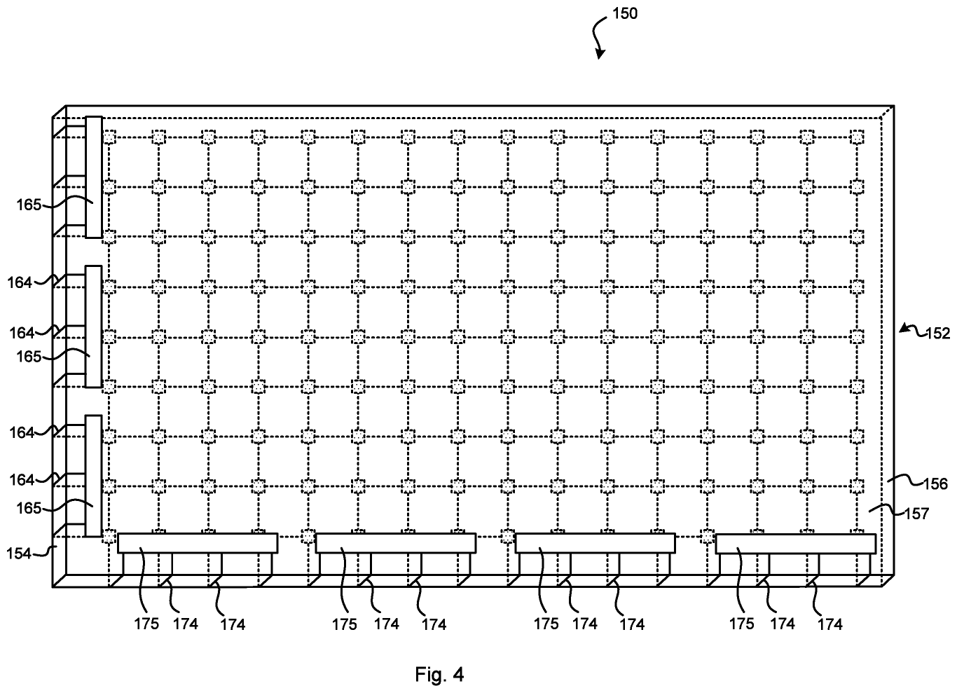

Turning to FIGS. 2-4, a display tile 150 is shown, which includes a first substrate 152 comprising a first surface 155, a second surface 157 opposite the first surface 155 and an edge surface 154 between the first surface 155 and the second surface 157, the edge surface 154 defining an outer perimeter 156 of the display tile.

The display tiles 150 described herein according to one or more embodiments can comprise a substrate 152 of any suitable material, for example, a polymeric substrate, printed circuit board, metal, glass-based, ceramic, sapphire, or silicon substrate having any desired size and/or shape appropriate to produce a display tile. The first surface 155 and second surface 157 may, in certain embodiments, be planar or substantially planar, e.g., substantially flat. The first surface 155 and the second surface 157 may, in various embodiments, be parallel or substantially parallel. The substrate 152 according to some embodiments may comprise four edges as illustrated in FIGS. 2-4, or may comprise more than four edges, e.g. a multi-sided polygon. In other embodiments, the display tile 150 may comprise less than four edges, e.g., a triangle. By way of a non-limiting example, the substrate 152 may comprise a rectangular, square, or rhomboid sheet having four edges, although other shapes and configurations are intended to fall within the scope of the disclosure including those having one or more curvilinear portions or edges.

In certain embodiments, substrate 152 may have a thickness d1 of less than or equal to about 3 mm. In some embodiments, thickness d1 is between 0.01 mm and three (3) mm. In some embodiments, thickness d1 is between 0.1 mm and 2.5 mm. In various embodiments, thickness d1 is between 0.3 mm and two (2) mm. In some embodiments, thickness d1 is between 0.3 mm and 1.5 mm. In some embodiments, thickness d1 is between 0.3 mm and one (1) mm. In some embodiments, thickness d1 is between 0.3 mm and 0.7 mm. In some embodiments, thickness d1 is between 0.3 mm and 0.5 mm.

The glass-based substrate used to manufacture the display tile can comprise any glass-based material known in the art for use in display devices. For example, the glass-based substrate may comprise aluminosilicate, alkali-aluminosilicate, borosilicate, alkali-borosilicate, aluminoborosilicate, alkali-aluminoborosilicate, soda lime, or other suitable glasses. Non-limiting examples of commercially available glasses suitable for use as a glass substrate include, for example, EAGLE XG®, Lotus™, Willow®, and Astra™ glasses from Corning Incorporated.

The first surface 155 of the display tile 150 includes an array of pixel elements 158 arranged in a plurality of rows 160 of pixel elements 158 and a plurality of columns 170 of pixel elements 158. Each row 160 of pixel elements 158 is connected by a row electrode 162, and each column 170 of pixel elements 158 is connected by a column electrode 172. It will be understood, that the rows 160 and columns 170 of pixel elements that intersect include some of the same pixel elements 158. Thus, there are not two separate sets of pixel elements 158, but one array of pixel elements 158 containing pixel elements 158 that are both connected to separate row and column electrodes. The display tile according to one or more embodiments includes at least one row driver 165 that electrically activates the rows 160 of pixel elements 158 and at least one column driver 175 that activates the columns 170 of pixel elements 158, the row drivers 165 and the column drivers 175 are located opposite the first surface 155. In the embodiment shown in FIGS. 2-4, the row drivers 165 and the column drivers 175 are located on the second surface 157 of the substrate 152. In other embodiments, the row drivers 165 and the column drivers 175 can be located on a separate structure disposed opposite the first surface 155, such as on a separate substrate (not shown) or other suitable structure. In some such cases, electrical contacts are located opposite the substrate first surface 157 that are then electrically connected to the row and column drivers either with a flex connector, solder connection, or other suitable method. Electrically coupling from one surface to an electrical contact on the opposite surface that is ultimately connected to a row or column driver is considered electrically coupling to the row or column driver.

As will be appreciated, the row drivers 165 and the column drivers 175 are connected to the row electrodes 162 and the column electrodes 172 to activate the pixel elements 158. A plurality of row electrode connectors 164 are provided, and each row electrode connector 164 is wrapped around the edge surface 154 and electrically connects a row electrode 162, a row 160 of pixel elements 158 and a row driver 165. The display tile shown further includes a plurality of column electrode connectors 174, each column electrode connector 174 wrapped around the edge surface 154 and electrically connecting a column electrode 172, a column 170 of pixel elements 158 and the column driver 175. In the embodiment shown, each row driver 165 is shown as connecting three rows 160 of row electrodes to pixel elements 158, and each column driver is shown as connecting four columns 170 of column electrodes 172 to pixel elements 158. It will be understood that this arrangement is for illustration purposes only, and the disclosure is not limited to any particular number of row drivers, column drivers or number of row electrode or column electrodes respectively driven by the row drivers and column drivers. For example, the electrode connectors can exist on only one or multiple edge surfaces 154 based on the specific display design and layout. Furthermore, the disclosure is not limited to any particular number of pixel elements 158 or arrangement of pixel elements 158 on the first surface 155 of the substrate 152. Although a matrix backplane design is described, alternative configurations are also possible. The electrical backplane circuitry described with row and column matrices can either be a passive matrix or active matrix design. If active matrix, the thin film transistor array can exist either on the first, second, or both substrate surfaces. Alternatively, the display backplane can include driver or micro-driver integrated circuits (IC) directly communicating with the pixels. These driver or micro-driver ICs can be located on the first, second, or both substrate surfaces or on a separate substrate that is electrically connected to the second surface of the substrate.

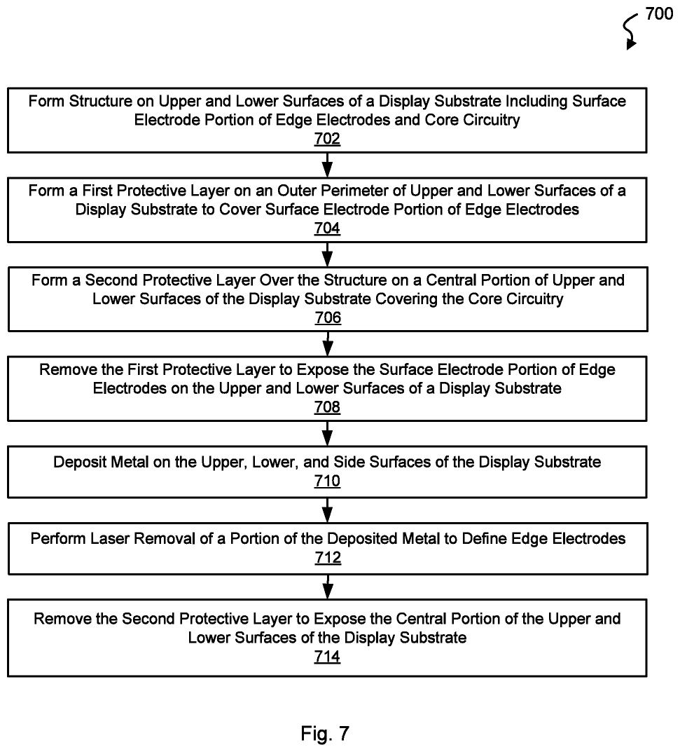

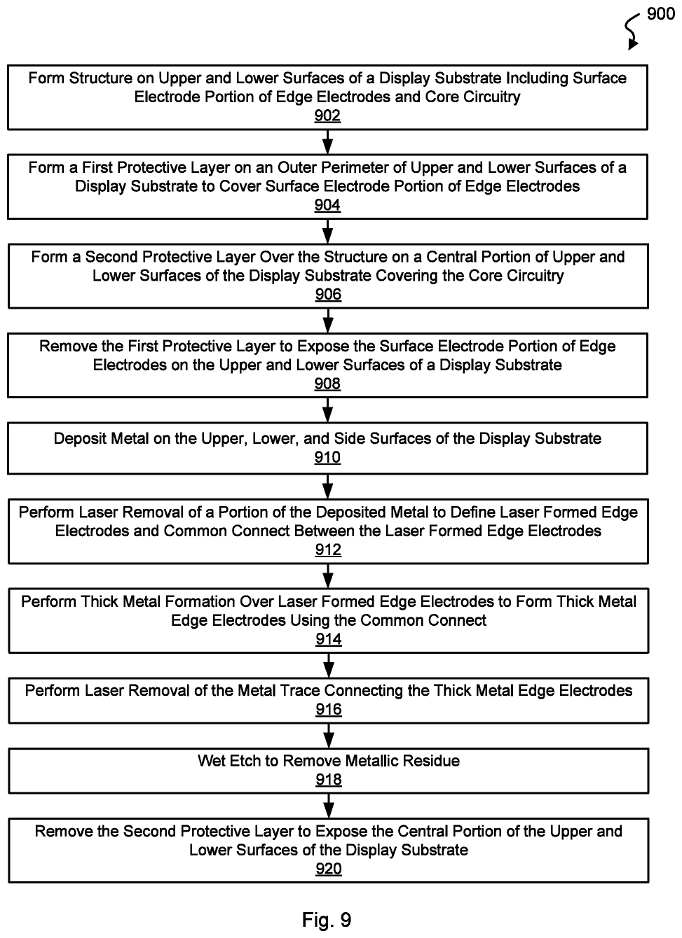

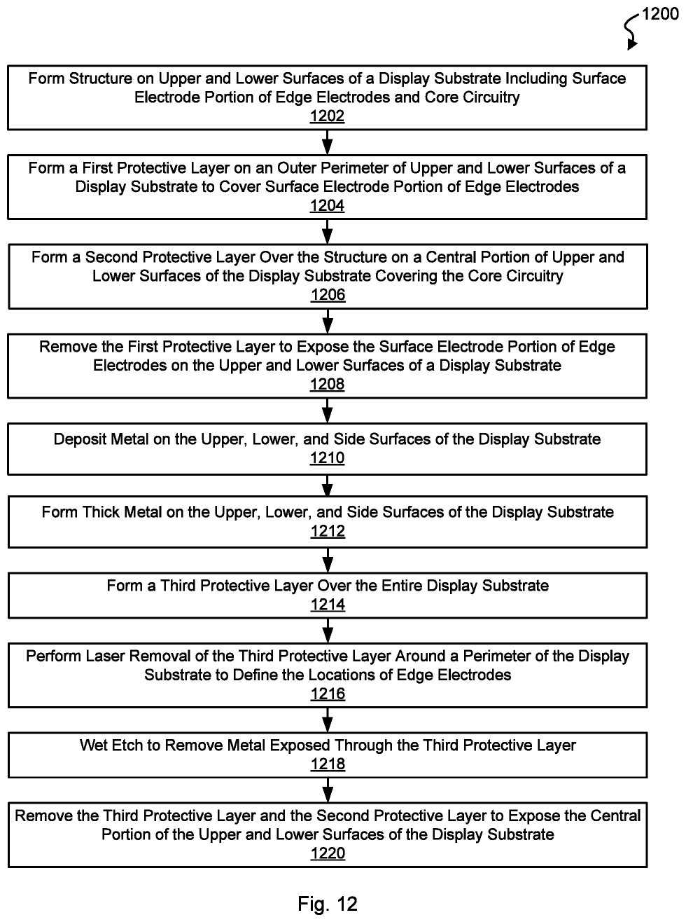

Any suitable connector type can be utilized to provide the row electrode connectors 164 and the column electrode connectors 174. Also, all of the electrode connectors do not need to be of the same type or design. In one or more embodiments, at least one row electrode connector 164 and at least one column electrode connector 174 comprises a thin electrode formed using, for example, the process discussed below in relation to FIG. 7. In various embodiments, at least one row electrode connector 164 and at least one column electrode connector 174 comprises a thick electrode formed using, for example, the process discussed below in relation to FIG. 9. In some embodiments, at least one row electrode connector 164 and at least one column electrode connector 174 comprises a thick electrode formed using, for example, the process discussed below in relation to FIG. 12.

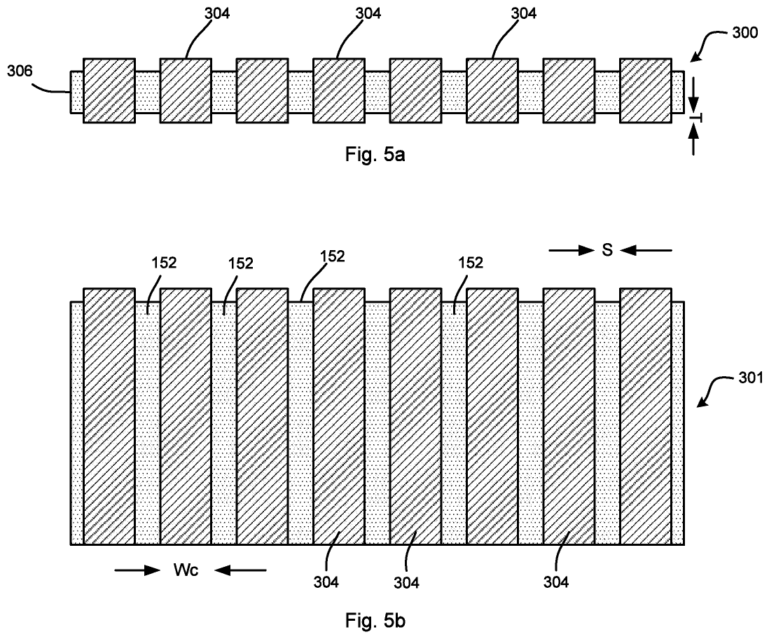

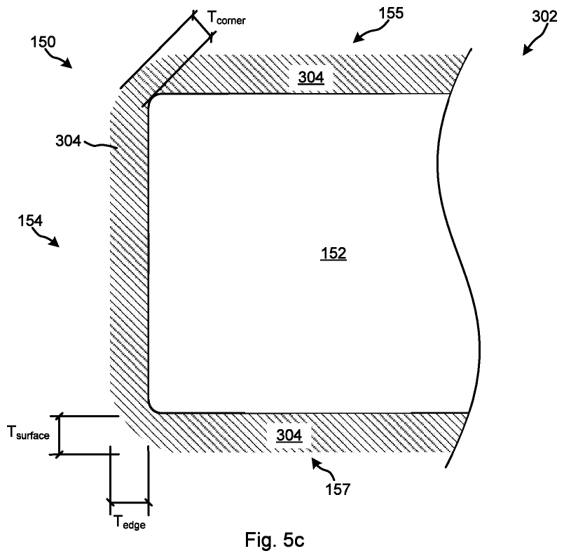

Turning to FIGS. 5a-5b, an end view 300 and a top view 301 of a portion of an edge of display tile 150 including a number of conductors 304 extending around an edge of a substrate 306 to connect opposing surfaces of substrate 152. These conductors 304 may be used to implement one or more of row electrode connectors 164 and/or column electrode connectors 174. As shown, conductors 304 exhibit a conductor width (Wc) and a conductor thickness (T). Conductor thickness (T) can be further refined to be a thickness along surfaces 155, 157 (Tsurface), a thickness along edge 154 (Tedge), and a thickness at the corner (Tcorner) as shown in FIG. 5c. Where a measurement of thickness (T) is discussed without specific reference to Tsurface, Tedge, or Tcorner, the measurement refers to the Tedge. Conductors 304 are separated by a spacing (S) from other conductors 304.

In some embodiments, spacing (S) is less than or equal to two hundred micrometers (200 μm). In other embodiments, spacing (S) is less than or equal to one hundred micrometers (100 μm). In yet further embodiments, spacing (S) is less than or equal to 5 micrometers (5 μm). In yet additional embodiments, spacing (S) is less than or equal to one micrometer (1 μm). In some embodiments, spacing (S) is less than or equal to two hundred, fifty nanometers (250 nm). In various embodiments, spacing (S) is less than or equal to one hundred twenty nanometers (120 nm).

In some embodiments, conductor thickness (T) is less than or equal to two micrometers (2 μm). Electrodes exhibiting such a thickness are referred to herein as “thin electrodes”. In various embodiments, conductor thickness (T) is less than or equal to one micrometer. (1 μm). In other embodiments, conductor thickness (T) is less than or equal to six hundred nanometers (600 nm). In other embodiments, conductor thickness (T) is less than or equal to four hundred nanometers (400 nm). In yet other embodiments, conductor thickness (T) is less than or equal to two hundred nanometers (200 nm).

In other embodiments, conductor thickness (T) is greater than two micrometers (2 μm). Electrodes exhibiting such a thickness are referred to herein as “thick electrodes”. In various embodiments, conductor thickness (T) is greater than or equal to four micrometers (4 μm). In further embodiments, conductor thickness (T) is greater than or equal to four micrometers (6 μm). In some embodiments, conductor thickness (T) is greater than or equal to ten micrometers (10 μm).

In some embodiments, conductor width (Wc) is less than or equal to two hundred micrometers (200 μm). In other embodiments, conductor width (Wc) is less than or equal to one hundred micrometers (100 μm). In yet further embodiments, conductor width (Wc) is less than or equal to 5 micrometers (5 μm). In yet additional embodiments, conductor width (Wc) is less than or equal to one micrometer (1 μm). In some embodiments, conductor width (Wc) is less than or equal to two hundred, fifty nanometers (250 nm). In various embodiments, conductor width (Wc) is less than or equal to one hundred twenty nanometers (120 nm).

Turning to FIG. 5c, a detailed view 302 of a single electrode 304 is shown where thickness along surfaces 155, 157 (Tsurface) and edge 154 (Tedge) are greater than a thickness (Tcorner) at the transition between surfaces 155, 157 and edge 154. In some embodiments, Tsurface is less than or equal to two hundred percent (200 percent) of Tcorner. In other embodiments, Tsurface is less than or equal to one hundred, fifty percent (150 percent) of Tcorner. In yet other embodiments, Tsurface is less than or equal to one hundred, twenty-five percent (125 percent) of Tcorner. In yet additional embodiments, Tsurface is less than or equal to one hundred, fifteen percent (115 percent) of Tcorner. In some embodiments, Tedge is less than or equal to two hundred, fifty percent (250 percent) of Tcorner. In other embodiments, Tedge is less than or equal to one hundred, sixty percent (160 percent) of Tcorner. In yet other embodiments, Tedge is less than or equal to one hundred, twenty-five percent (125 percent) of Tcorner. In yet additional embodiments, Tedge is less than or equal to one hundred, fifteen percent (115 percent) of Tcorner. Tcorner might be either thinner or thicker than Tsurface depending on the vertical/horizontal plating. Generally, thicker Tcorner could reduce electrical discontinuity; but might cause high stress if thickness is too thick.

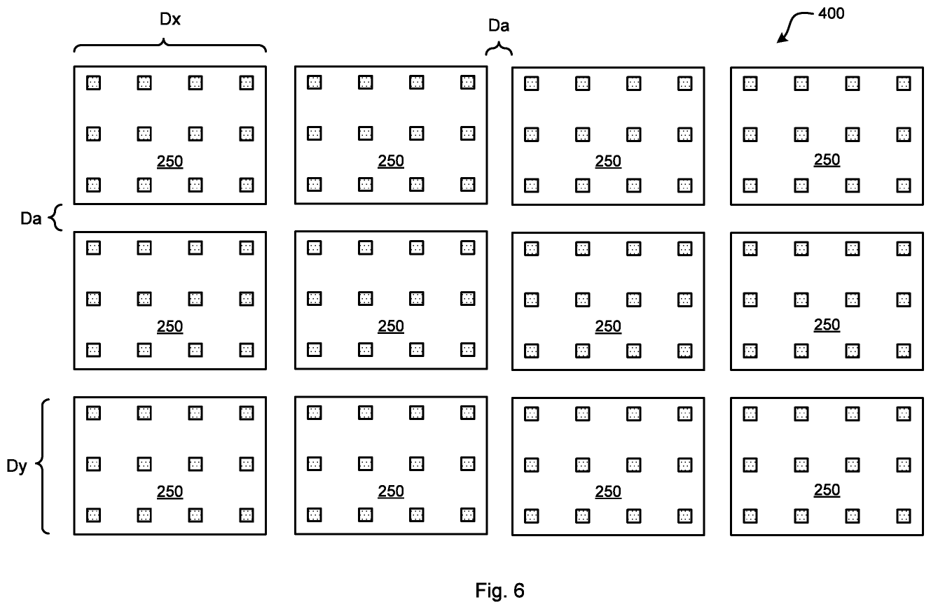

Turning to FIG. 6, a top perspective view of a display 400 (i.e., a tiled display) including a number of display tiles 250 spaced a sufficient distance from one another to accommodate side electrodes on respective display tiles. Each display tile 250 exhibits a width (Dx) and a height (Dy). Each of display tiles 250 is separated a spacing (Da) from the next display tile. A non-zero value for Da results in an increased pixel pitch (i.e., distance between adjacent pixels) at the transition between display tiles. By reducing the distance Da, the pixel pitch at the transition between display tiles and the ratio of non-effective display area to overall display area (i.e., the sum of the non-effective display area and the effective display area) decreases. By reducing the distance Da to approximately zero, the aforementioned ratio approaches zero and provides for a better visual experience when using such a display.

Where, for example, display tiles 250 are manufactured in accordance with the display tiles of FIGS. 5a-5c such that conductors 304 wrap around two adjacent sides of the display tiles, spacing Da can be reduced to slightly greater than the thickness of the electrodes at an end (Tedge) of a display tile. Where, as another example, display tiles 250 are manufactured in accordance with the display tiles of FIGS. 5a-5c such that conductors 304 wrap around all sides of the display tiles, spacing Da can be reduced to slightly greater than two times the thickness of the electrodes at an end (Tedge) of a display tile.

The display 400 can be any type of display including, but not limited to, a liquid crystal display (LCD), a light emitting diode (LED) display, a microLED, an electrophoretic display, an e-paper display, and an organic light emitting diode (OLED) display. In some embodiments, the display is a LED and the pixel elements are microLEDs located within five hundred (500) micrometers of an edge surface of at least one display tile 250. In some embodiments, the display is a LED and the pixel elements are microLEDs located within four hundred (400) micrometers of an edge surface of at least one display tile 250. In various embodiments, the display is a LED display and the pixel elements are microLEDs located within three hundred (300) micrometers of an edge surface of at least one display tile 250. In some embodiments, the display is a LED display and the pixel elements are microLEDs located within two hundred (200) micrometers of an edge surface of at least one display tile 250. In various embodiments, the display is a LED display and the pixel elements are microLEDs located within one hundred (100) micrometers of an edge surface of at least one display tile 250. In some embodiments, the display is a LED display and the pixel elements are microLEDs located within twenty (20) micrometers of an edge surface of at least one display tile 250. Alternatively to the tiled display as shown in FIG. 6, a single individual substrate can be used within a display device.

Turning to FIG. 7, a flow diagram 700 shows a method in accordance with some embodiments for forming wrap-around, edge electrodes using a laser removal process. Following flow diagram 700, structure is formed on upper and/or lower surfaces of a display substrate (block 702). The structures include core circuitry and surface electrode portions of wrap-around edge electrodes. The core circuitry and surface electrode portions of wrap-around edge electrodes may be formed using any suitable technology known in the art.

The display substrate may be made of any suitable material, for example, a polymeric substrate, printed circuit board, metal, or a glass-based substrate having any desired size and/or shape appropriate to produce a display tile. In some embodiments, the substrate may be, but is not limited to, a rectangular, square, or rhomboid sheet having four edges, although other shapes and configurations are intended to fall within the scope of the disclosure including those having one or more curvilinear portions or edges. In various embodiments, the substrate may have a thickness d1 of less than or equal to about 3 mm. In some embodiments, the thickness of the substrate is between 0.01 mm and three (3) mm. In some embodiments, the substrate thickness is between 0.1 mm and 2.5 mm. In various embodiments, the substrate thickness is between 0.3 mm and two (2) mm. In some embodiments, the substrate thickness is between 0.3 mm and 1.5 mm. In some embodiments, the substrate thickness between 0.3 mm and one (1) mm. In some embodiments, the substrate thickness is between 0.3 mm and 0.7 mm. In various embodiments, the substrate thickness is between 0.3 mm and 0.5 mm.

In some embodiments, the substrate is a glass-based substrate. For example, such a glass-based substrate may comprise aluminosilicate, alkali-aluminosilicate, borosilicate, alkali-borosilicate, aluminoborosilicate, alkali-aluminoborosilicate, soda lime, or other suitable glasses. Non-limiting examples of commercially available glasses suitable for use as a glass substrate include, for example, EAGLE XG®, Lotus™, Willow®, and Astra™ glasses from Corning Incorporated.

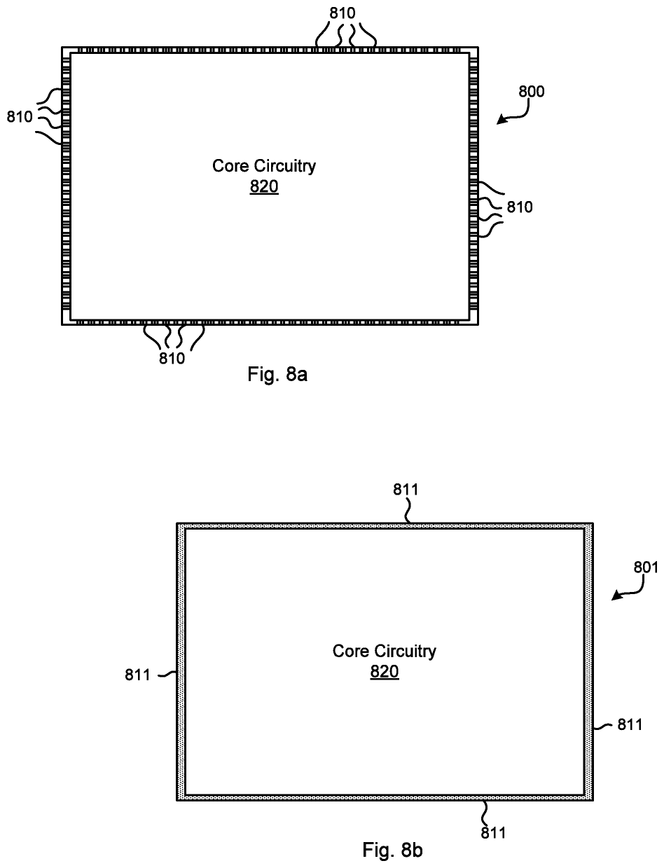

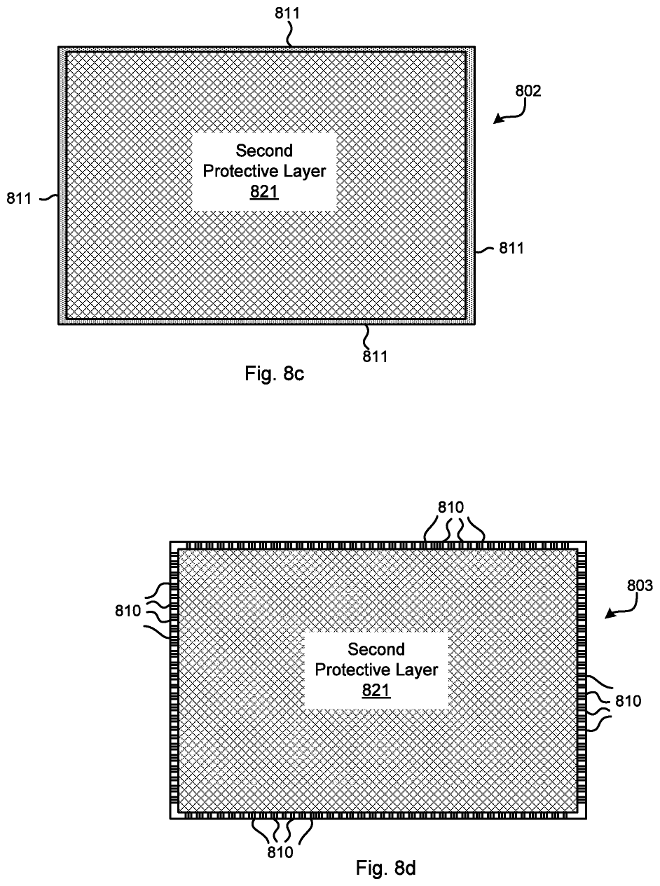

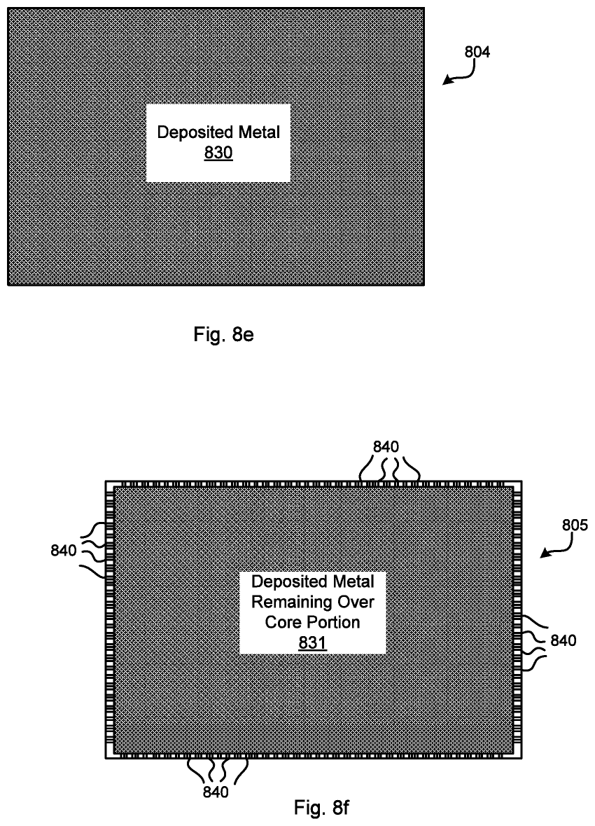

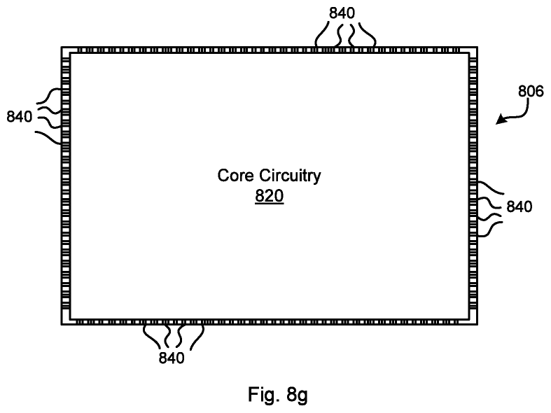

The core circuitry may include, but is not limited to, column driver circuits, row driver circuits, light emitting diodes, and conductive interconnect formed or placed in a central region of one or both of a top surface and a bottom surface of the substrate. In some cases, thin film transistor technology is used to form at least a part of the core circuitry. Based upon the disclosure provided herein, one of ordinary skill in the art will recognize a variety of circuitry and/or interconnect that may be incorporated into the core circuitry. The surface electrode portion of various wrap-around, edge electrodes are formed around a periphery of the substrate and extend from contact locations within the core circuitry to the edge of the substrate. Turning to FIG. 8a, an example of a display tile 800 having a substrate including core circuitry 820 in a central region and surface electrode portions 810 of wrap-around edge electrodes around a periphery of the substrate is shown.

Returning to FIG. 7, a first protective layer is formed on an outer perimeter of the display substrate to protect the surface electrode portions (block 704). The first protective layer may be made of any material capable of protecting surface electrode portions during various processes including eventual removal of the material to expose the surface electrode portions. Further, application of the material of the first protective material may be done using any suitable application process known in the art. In some embodiments, a polyimide (PI) tape is applied around the perimeter of the substrate to protect the surface electrode portions. In other embodiments, a combination of one or more of PI, polyurethane (PU), and/or cyclic olefin copolymers are applied around the perimeter of the substrate to protect the surface electrode portions. Based upon the disclosure provided herein, one of ordinary skill in the art will recognize a variety of materials and application processes that may be used to form the first protective layer in accordance with different embodiments. Turning to FIG. 8b, an example of a display tile 801 having a substrate including core circuitry 820 in a central region and surface electrode portions (not shown) covered by a first protective layer 811 is shown.

Returning to FIG. 7, a second protective layer is formed over the core structure of the substrate to protect core circuitry, interconnect, and other structure during processing (block 706). The second protective layer may be made of any material capable of protecting the core structure during various processes including eventual removal of the first protective layer and the material of the second protective layer. Further, application of the material of the second protective material may be done using any suitable application process known in the art. In some embodiments, a standard thin film transistor protection material is deposited over the core structure. Based upon the disclosure provided herein, one of ordinary skill in the art will recognize a variety of materials and application processes that may be used to form the second protective layer in accordance with different embodiments. Turning to FIG. 8c, an example of a display tile 802 having a substrate with core circuitry (not shown) covered by a second protective layer 821 is shown. It should be noted that in some embodiments the second protective layer covers both the core structure and at least part of the first protective layer.

Returning to FIG. 7, the first protective layer is removed leaving the surface electrode portions exposed (block 708). This is done by exposing the display substrate with a chemical and/or mechanical process that removes the first protective layer while leaving the second protective layer over the core structure. Where, for example, the first protective layer is PI tape, removal of the first protective layer is done by peeling the PI tape away from the display tile. In cases where the second protective layer at least partially covered the first protective layer, removal of the first protective layer removes any portion of the second protective layer disposed over the first protective layer. Turning to FIG. 8d, an example of a display tile 803 having a substrate with core circuitry (not shown) covered by the second protective layer 821 and the surface electrode portions 810 exposed is shown.

Returning to FIG. 7, metal is deposited over all surfaces of the display tile (block 710). Any process for depositing metal may be used. In some embodiments, the metal deposition includes sputtering pure copper (Cu), silver (Ag), gold (Au), nickel (Ni), or their combinations. Based upon the disclosure provided herein, one of ordinary skill in the art will recognize a variety of metals or other conductive materials that may be used in relation to different embodiments, and/or a variety of processes that may be used to cover the display tile with the selected metal or other conductive material. Turning to FIG. 8e, an example of a display tile 804 having a substrate with core circuitry (not shown) and surface electrode portions (not shown) that are covered by a deposited metal 830 is shown. The deposited metal 830 covers all sides of the display tile.

Returning to FIG. 7, laser removal of a portion of the deposited metal is performed to define wrap-around, edge electrodes (block 712). Such laser removal is done along the periphery of the display tile and includes removal of all metal or other conductive material from areas extending from a first surface of the display device across the edge of the display device to a second surface of the display device where a wrap-around electrode is not desired. In some embodiments, this process of laser removal is done by mounting the display tile in relation to a laser energy source such that the display tile can be moved relative to the laser energy source in three dimensions. Application of the laser energy to the metal ablates the metal and in some cases a portion of the substrate lying under the metal. Turning to FIG. 8f, an example of a display tile 805 having a substrate with core circuitry (not shown) covered by the second protective layer 821 and/or a deposited metal remaining over the core portion 831 and laser defined wrap-around, edge electrodes 840 is shown. Wrap-around, edge electrodes 840 extend from a surface of the display tile 805 across the edge of the display tile 805 to an opposite surface of display tile 805. In some embodiments, the thickness of wrap-around, edge electrodes 840 is less than or equal to two micrometers (2 μm). In various embodiments, the thickness of wrap-around, edge electrodes 840 is less than or equal to one micrometer. (1 μm). In other embodiments, the thickness of wrap-around, edge electrodes 840 is less than or equal to six hundred nanometers (600 nm). In other embodiments, the thickness of wrap-around, edge electrodes 840 is less than or equal to four hundred nanometers (400 nm). In yet other embodiments, the thickness of wrap-around, edge electrodes 840 is less than or equal to two hundred nanometers (200 nm).

Use of such laser removal processing provides for creating fine line width and spacing when compared with approaches. In some embodiments, spacing between wrap-around, edge electrodes of less than or equal to one hundred micrometers (100 μm) is achieved. In other embodiments, spacing between wrap-around, edge electrodes of less than or equal to fifty micrometers (50 μm) is achieved. In yet further embodiments, spacing between wrap-around, edge electrodes of less than or equal to 5 micrometers (5 μm) is achieved where a femto second (fs) laser relying on two photon absorption is used. In yet additional embodiments, spacing between wrap-around, edge electrodes of less than or equal to one micrometer (1 μm) is achieved where a femto second (fs) laser relying on two photon absorption is used. In some embodiments, spacing between wrap-around, edge electrodes of less than or equal to two hundred, fifty nanometers (250 nm) is achieved where a femto second (fs) laser relying on two photon absorption is used. In various embodiments, spacing between wrap-around, edge electrodes of less than or equal to one hundred twenty nanometers (120 nm) is achieved where a femto second (fs) laser relying on two photon absorption is used. In some embodiments, a width of wrap-around, edge electrodes of less than or equal to one hundred micrometers (100 μm) is achieved. In other embodiments, a width of wrap-around, edge electrodes of less than or equal to fifty micrometers (50 μm) is achieved. In yet further embodiments, a width of wrap-around, edge electrodes of less than or equal to 5 micrometers (5 μm) is achieved where a femto second (fs) laser relying on two photon absorption is used. In yet additional embodiments, a width of wrap-around, edge electrodes of less than or equal to one micrometer (1 μm) is achieved where a femto second (fs) laser relying on two photon absorption is used. In some embodiments, a width of wrap-around, edge electrodes of less than or equal to two hundred, fifty nanometers (250 nm) is achieved where a femto second (fs) laser relying on two photon absorption is used. In various embodiments, a width of wrap-around, edge electrodes of less than or equal to one hundred twenty nanometers (120 nm) is achieved where a femto second (fs) laser relying on two photon absorption is used. Further, use of such laser removal processing offers smaller wrap-around, edge electrode widths and higher purity metals when compared with pen dispensing which is typically limited to dimensions of more than one hundred micrometers (100 μm). After laser ablation, wet clean process might be needed to help completely remove metallic residue in the ablation area.

Returning to FIG. 7, the second protective layer (and an overlying layer of metal) is removed to expose the central portion of the display tile with its core circuitry and/or structure (block 714). This may be done by exposing the display tile to a solvent designed to selectively impact the material of the second protective layer. In some cases, where the material of the second protective layer is a polymer, such as completely cross-linked or partial cross-linked PU (polyurethane), the solvent is alcohol, an acetone, or water that causes the material of the second protective layer to swell and remove the polymer from the display tile. In some cases, the laser ablation performed to remove metal from areas where a wrap-around, edge electrode is continued to remove some amount of the underlying display substrate such that trenches are left. These trenches further enhance the ability for the solvents applied to move under the second protective layer that is covered by the deposited metal. Based upon the disclosure provided herein, one of ordinary skill in the art will recognize a variety of removal materials and/or removal processes that may be used to remove the second protective layer. Turning to FIG. 8g, an example of a display tile 806 having a substrate with a core circuitry 820 exposed and wrap-around, edge electrodes 840.

As an alternative to the process discussed in relation to FIG. 7, thin film transistor processing may be used to form wrap-around side electrodes after formation of the second protective layer (i.e., block 706) and removal of the first protective layer (i.e., block 708). In such an approach the polymer of the second protective layer reduces the area of the laser removal (i.e., block 712). This allows for relatively quick removal of metal in areas where wrap-around, edge electrodes are desired by application of solvents selective to the metal.

Turning to FIG. 9, a flow diagram 900 shows a method in accordance with some embodiments for forming wrap-around, edge electrodes using a laser removal process. Following flow diagram 900, structure is formed on upper and/or lower surfaces of a display substrate (block 902). The structures include core circuitry and surface electrode portions of wrap-around edge electrodes. The core circuitry and surface electrode portions of wrap-around edge electrodes may be formed using any suitable technology known in the art.

The display substrate may be made of any suitable material, for example, a polymeric substrate, printed circuit board, metal, glass-based, ceramic, sapphire, or silicon substrate having any desired size and/or shape appropriate to produce a display tile. In some embodiments, the substrate may be, but is not limited to, a rectangular, square, or rhomboid sheet having four edges, although other shapes and configurations are intended to fall within the scope of the disclosure including those having one or more curvilinear portions or edges. In various embodiments, the substrate may have a thickness d1 of less than or equal to about 3 mm. In some embodiments, the thickness of the substrate is between 0.01 mm and three (3) mm. In some embodiments, the substrate thickness is between 0.1 mm and 2.5 mm. In various embodiments, the substrate thickness is between 0.3 mm and two (2) mm. In some embodiments, the substrate thickness is between 0.3 mm and 1.5 mm. In some embodiments, the substrate thickness between 0.3 mm and one (1) mm. In some embodiments, the substrate thickness is between 0.3 mm and 0.7 mm. In various embodiments, the substrate thickness is between 0.3 mm and 0.5 mm.

In some embodiments, the substrate is a glass-based, ceramic, sapphire, Si, polymer, print circuit board (PCB)-based substrate. For example, such a glass-based substrate may comprise aluminosilicate, alkali-aluminosilicate, borosilicate, alkali-borosilicate, aluminoborosilicate, alkali-aluminoborosilicate, soda lime, or other suitable glasses. Non-limiting examples of commercially available glasses suitable for use as a glass substrate include, for example, EAGLE XG®, Lotus™, Willow®, and Astra™ glasses from Corning Incorporated.

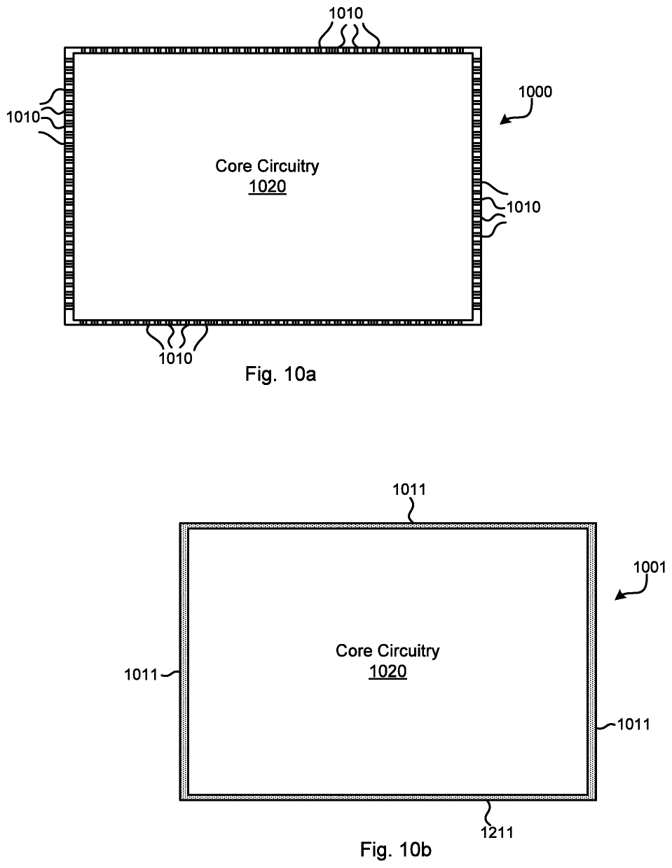

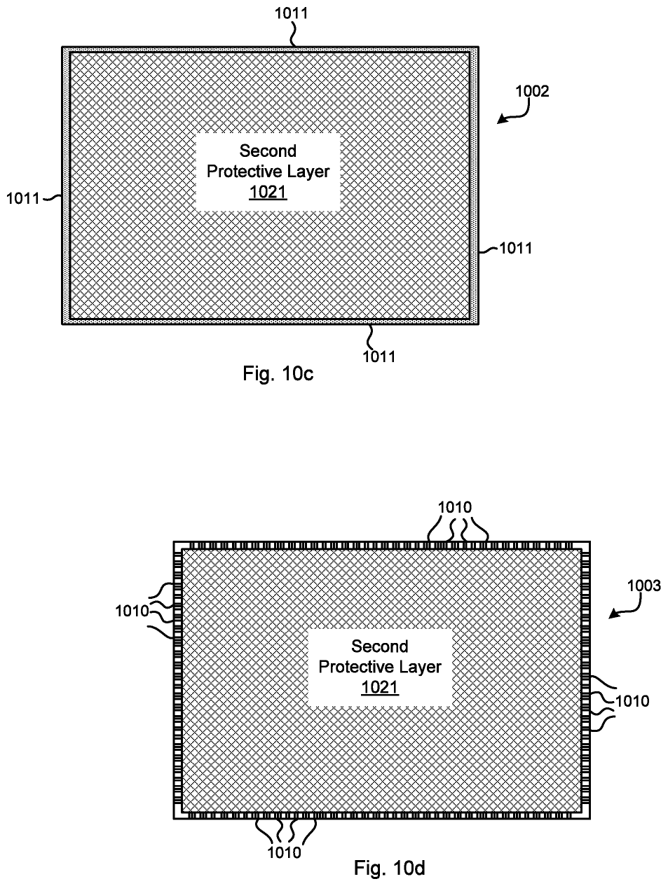

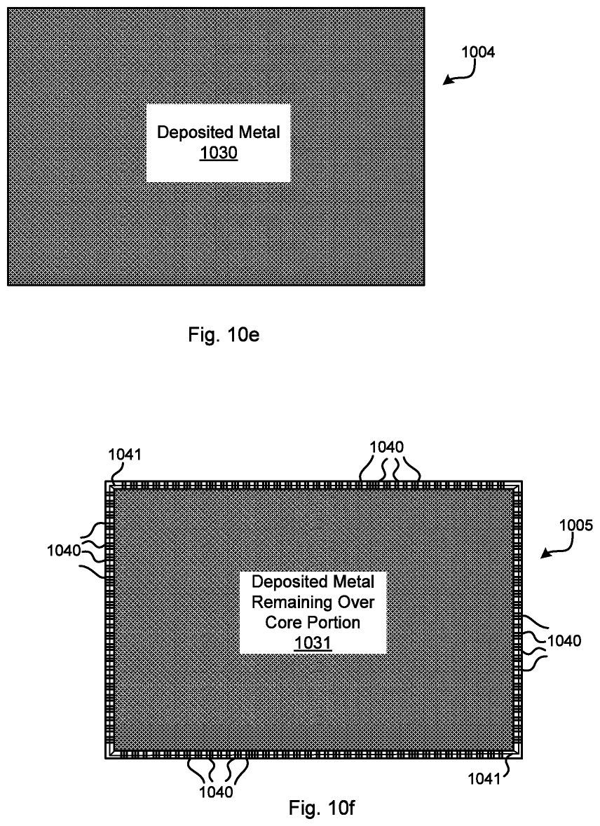

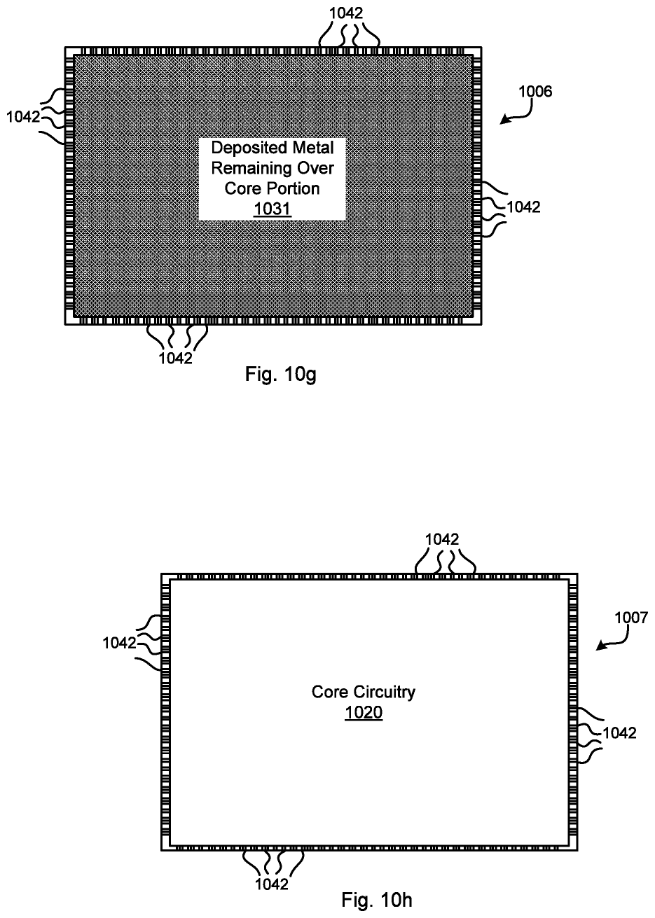

The core circuitry may include, but is not limited to, column driver circuits, row driver circuits, light emitting diodes, and conductive interconnect formed or placed in a central region of one or both of a top surface and a bottom surface of the substrate. In some cases, thin film transistor technology is used to form at least a part of the core circuitry. Based upon the disclosure provided herein, one of ordinary skill in the art will recognize a variety of circuitry and/or interconnect that may be incorporated into the core circuitry. The surface electrode portion of various wrap-around, edge electrodes are formed around a periphery of the substrate and extend from contact locations within the core circuitry to the edge of the substrate. Turning to FIG. 10a, an example of a display tile 1000 having a substrate including core circuitry 1020 in a central region and surface electrode portions 1010 of wrap-around edge electrodes around a periphery of the substrate is shown.

Returning to FIG. 9, a first protective layer is formed on an outer perimeter of the display substrate to protect the surface electrode portions (block 904). The first protective layer may be made of any material capable of protecting surface electrode portions during various processes including eventual removal of the material to expose the surface electrode portions. Further, application of the material of the first protective material may be done using any suitable application process known in the art. In some embodiments, a polyimide (PI) tape is applied around the perimeter of the substrate to protect the surface electrode portions. In other embodiments, a combination of one or more of PI, polyurethane (PU), and/or cyclic olefin copolymers are applied around the perimeter of the substrate to protect the surface electrode portions. Based upon the disclosure provided herein, one of ordinary skill in the art will recognize a variety of materials and application processes that may be used to form the first protective layer in accordance with different embodiments. Turning to FIG. 10b, an example of a display tile 1001 having a substrate including core circuitry 1020 in a central region and surface electrode portions (not shown) covered by a first protective layer 1011 is shown.

Returning to FIG. 9, a second protective layer is formed over the core structure of the substrate to protect core circuitry, interconnect, and other structure during processing (block 906). The second protective layer may be made of any material capable of protecting the core structure during various processes including eventual removal of the first protective layer and the material of the second protective layer. Further, application of the material of the second protective material may be done using any suitable application process known in the art. In some embodiments, a standard thin film transistor protection material is deposited over the core structure. Based upon the disclosure provided herein, one of ordinary skill in the art will recognize a variety of materials and application processes that may be used to form the second protective layer in accordance with different embodiments. Turning to FIG. 10c, an example of a display tile 1002 having a substrate with core circuitry (not shown) covered by a second protective layer 1021 is shown. It should be noted that in some embodiments the second protective layer covers both the core structure and at least part of the first protective layer.

Returning to FIG. 9, the first protective layer is removed leaving the surface electrode portions exposed (block 908). This is done by exposing the display substrate with a chemical and/or mechanical process that removes the first protective layer while leaving the second protective layer over the core structure. Where, for example, the first protective layer is PI tape, removal of the first protective layer is done by peeling the PI tape away from the display tile. In cases where the second protective layer at least partially covered the first protective layer, removal of the first protective layer removes any portion of the second protective layer disposed over the first protective layer. Turning to FIG. 10d, an example of a display tile 1003 having a substrate with core circuitry (not shown) covered by the second protective layer 1021 and the surface electrode portions 1010 exposed is shown.

Returning to FIG. 9, metal is deposited over all surfaces of the display tile to yield a thin metal coating (i.e., less than or equal to two micrometers (2 μm) in thickness) (block 910). Any process for depositing metal may be used. In some embodiments, the metal deposition includes sputtering pure copper (Cu), silver (Ag), gold (Au), nickel (Ni), or their combinations. In other cases, the pure metal is a dual layer structure, such as Ti/Cu, TiW/Cu, TiN/Cu, Cr/Cu, where Ti, TiW, TiN or Cr is adhesion layer between pure metal and substrate. Based upon the disclosure provided herein, one of ordinary skill in the art will recognize a variety of metals or other conductive materials that may be used in relation to different embodiments, and/or a variety of processes that may be used to cover the display tile with the selected metal or other conductive material. Turning to FIG. 10e, an example of a display tile 1004 having a substrate with core circuitry (not shown) surface electrode portions (not shown) that are covered by a deposited metal 1030 is shown. The deposited metal 1030 covers all sides of the display tile.

Returning to FIG. 9, laser removal of a portion of the deposited metal around a perimeter of the display substrate to define wrap-around edge electrodes is performed (block 912). This laser removal leaves a metal trace that extends approximately perpendicular to the defined wrap-around, edge electrodes resulting in an electrical connection between the wrap-around, edge electrodes. Such laser ablation leaves thin electrodes approximately the thickness of the previously deposited metal layer. Such laser removal is done along the periphery of the display tile and includes removal of all metal or other conductive material from areas extending from a first surface of the display device across the edge of the display device to a second surface of the display device where a wrap-around electrode is not desired. In some embodiments, this process of laser removal is done by mounting the display tile in relation to a laser energy source such that the display tile can be moved relative to the laser energy source in three dimensions. Application of the laser energy to the metal ablates the metal and in some cases a portion of the substrate lying under the metal. Turning to FIG. 10f, an example is shown of a display tile 1005 having a substrate with core circuitry (not shown) covered by the second protective layer 1021 and/or a deposited metal remaining over the core portion 1031, laser defined wrap-around, edge electrodes 1040, and a metal trace 1041 electrically connecting the wrap-around, edge electrodes 1040. Wrap-around, edge electrodes 1040 extend from a surface of the display tile 1005 across the edge of the display tile 1005 to an opposite surface of display tile 1005. In some embodiments, the thickness of wrap-around, edge electrodes 1040 is less than or equal to two micrometers (2 μm). In various embodiments, the thickness of wrap-around, edge electrodes 1040 is less than or equal to one micrometer. (1 μm). In other embodiments, the thickness of wrap-around, edge electrodes 1040 is less than or equal to six hundred nanometers (600 nm). In other embodiments, the thickness of wrap-around, edge electrodes 1040 is less than or equal to four hundred nanometers (400 nm). In yet other embodiments, the thickness of wrap-around, edge electrodes 1040 is less than or equal to two hundred nanometers (200 nm).

Either electroplating or electroless plating is applied to cover the entire surface of the display substrate with a thick metal layer (i.e., greater than or equal to two micrometers (2 μm) in thickness) (block 914). Where electroplating is performed, the metal trace electrically connecting the wrap-around edge electrodes is used to charge the electrodes for plating.

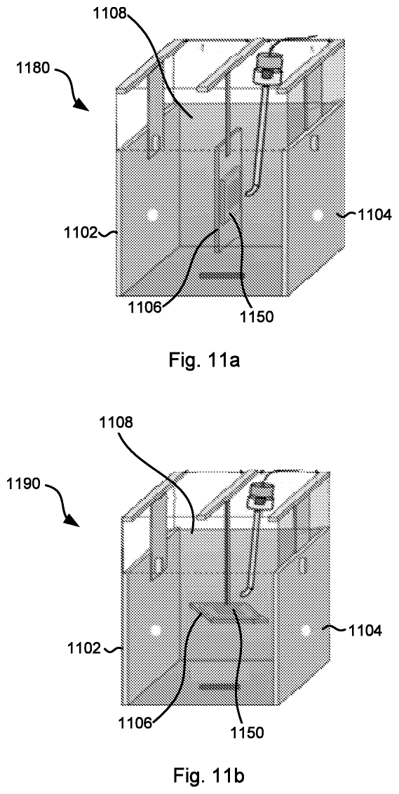

Such electroplating may be done in a plating bath where the display substrate is suspended in the plating bath in either a horizontal or vertical orientation. Turning to FIG. 11a, a plating bath 1180 is shown where a display substrate 1150 is attached to a carrier 1106 and suspended in a plating solution 1108 in a vertical orientation between two electrodes 1102, 1104. Turning to FIG. 11b, a plating bath 1190 is shown where display substrate 1150 is attached to carrier with a cavity in the middle 1106 and suspended in plating solution 1108 in a horizontal orientation between two potentials 1102, 1104.

During electroplating in some cases, the difference in thickness of the wrap-around edge electrode at the corner (Tcorner form FIG. 5c) is assured to not be significantly less than the thickness of the wrap-around edge electrode at the edge surface (Tedge from FIG. 5c) or at the surfaces (Tsurface from FIG. 5c). Where the corner thickness (Tcorner) is too small, it may result in a discontinuity after a later etching process or after application of electrical currents through the wrap-around, edge electrode. Experimental data has shown that thickness differences are greatest when the display substrate is suspended in the plating bath in the vertical orientation. In this orientation, the thickness of the surfaces (Tsurface) can be one hundred, fifty (150) percent of the thickness of the corner (Tcorner), and the thickness of the edge surface (Tedge) can be two hundred, twenty-five (225) percent of the thickness of the corner (Tcorner). In contrast, in the horizontal orientation, the thickness of the surfaces (Tsurface) can be less than one hundred, twenty percent (120) of the thickness of the corner (Tcorner), and the thickness of the edge surface (Tedge) can be less than one hundred, twenty percent (120) of the thickness of the corner (Tcorner).

Returning to FIG. 9, laser removal of the metal trace that connected the wrap-around, edge electrodes (block 916). As the metal trace is not included where electroless plating is performed, this process is not performed for a process relying on electroless plating. This removal process removes all metal disposed between adjacent wrap-around, edge electrodes leaving the adjacent edge electrodes electrically isolated from one another. In some cases, this process further ablates some of the substrate located between the wrap-around, edge electrodes leaving a channel for solvents to move under the second protective layer in a later process. Turning to FIG. 10g, an example of a display tile 1006 having a substrate with core circuitry (not shown) covered by a remaining deposited metal portion 1031, and thick wrap-around, edge electrodes 1042 is shown. Of note, metal trace 1041 has been removed. In various embodiments, the thickness of wrap-around, edge electrodes 1042 is greater than or equal to three micrometers (3 μm). In some embodiments, the thickness of wrap-around, edge electrodes 1042 is greater than or equal to four micrometers (4 μm). In further embodiments, the thickness of wrap-around, edge electrodes 1042 is greater than or equal to five micrometers (5 μm). In some embodiments, the thickness of wrap-around, edge electrodes 1042 is greater than or equal to ten micrometers (10 μm).

Returning to FIG. 9, a wet etch is applied to the display tile to remove all metal exposed by the laser removal of the third protective layer (block 918). For copper etching, acetic acid, or mixed phosphoric acid (HPO₃) with hydrogen peroxide (H₂O₂) or mixed sulfuric acid (H₂SO₄) with hydrogen peroxide (H₂O₂) or mixed FeCl₃ with HCl is applied. For titanium etching, buffer oxide etching (BOE), or diluted HF, or mixed hydrogen peroxide, sodium hydrogen phosphate and sodium fluorosilicate is used. This etching leaves thick wrap-around, edge electrodes defined around the perimeter of the display tile. Next, the second protective layer and the third protective layer are removed (block 920). Where the second and third protective layers are polymer layers, a solvent such as, for example, alcohol. acetone, or water with or without ultrasonication can be used. Turning to FIG. 10h, an example of a display tile 1007 having a substrate with core circuitry 1020 and thick wrap-around, edge electrodes is shown.

Turning to FIG. 12, a flow diagram 1200 shows a method in accordance with some embodiments for forming wrap-around, edge electrodes using a laser removal process. Following flow diagram 1200, structure is formed on upper and/or lower surfaces of a display substrate (block 1202). The structures include core circuitry and surface electrode portions of wrap-around edge electrodes. The core circuitry and surface electrode portions of wrap-around edge electrodes may be formed using any suitable technology known in the art.

The display substrate may be made of any suitable material, for example, a polymeric substrate, printed circuit board, metal, glass-based, ceramic, sapphire, or silicon substrate having any desired size and/or shape appropriate to produce a display tile. In some embodiments, the substrate may be, but is not limited to, a rectangular, square, or rhomboid sheet having four edges, although other shapes and configurations are intended to fall within the scope of the disclosure including those having one or more curvilinear portions or edges. In various embodiments, the substrate may have a thickness d1 of less than or equal to about 3 mm. In some embodiments, the thickness of the substrate is between 0.01 mm and three (3) mm. In some embodiments, the substrate thickness is between 0.1 mm and 2.5 mm. In various embodiments, the substrate thickness is between 0.3 mm and two (2) mm. In some embodiments, the substrate thickness is between 0.3 mm and 1.5 mm. In some embodiments, the substrate thickness between 0.3 mm and one (1) mm. In some embodiments, the substrate thickness is between 0.3 mm and 0.7 mm. In various embodiments, the substrate thickness is between 0.3 mm and 0.5 mm.

In some embodiments, the substrate is a glass-based substrate. For example, such a glass-based substrate may comprise aluminosilicate, alkali-aluminosilicate, borosilicate, alkali-borosilicate, aluminoborosilicate, alkali-aluminoborosilicate, soda lime, or other suitable glasses. Non-limiting examples of commercially available glasses suitable for use as a glass substrate include, for example, EAGLE XG®, Lotus™, Willow®, and Astra™ glasses from Corning Incorporated.

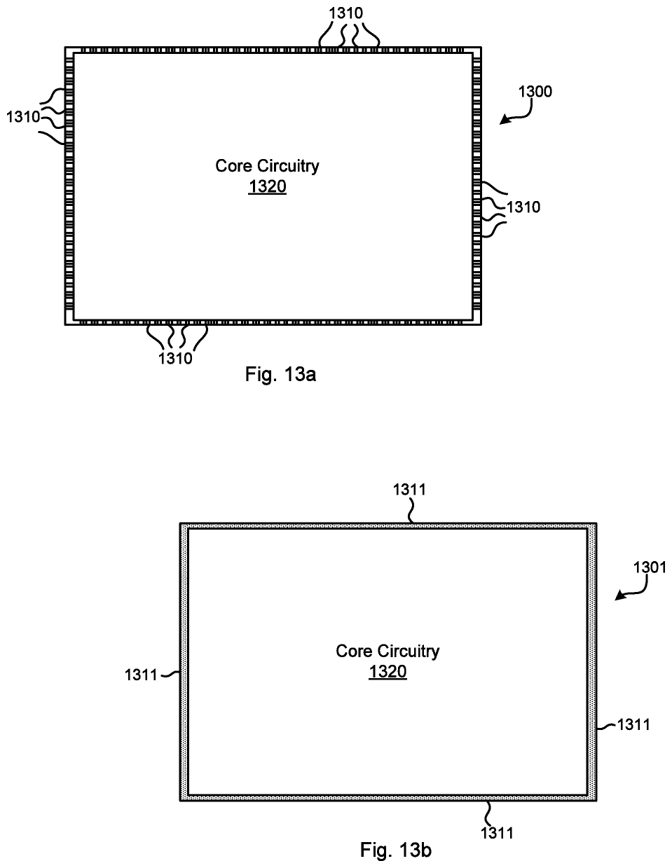

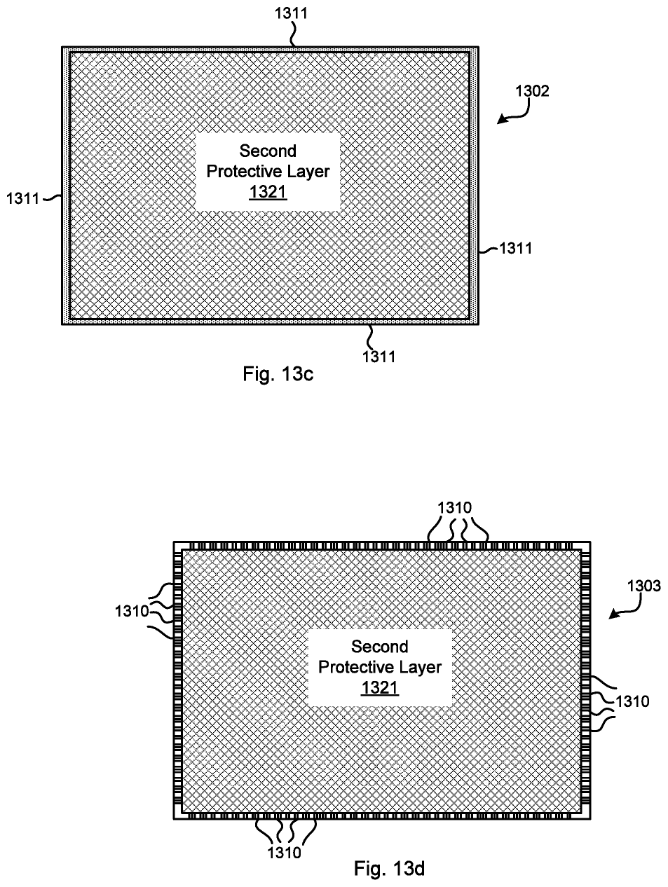

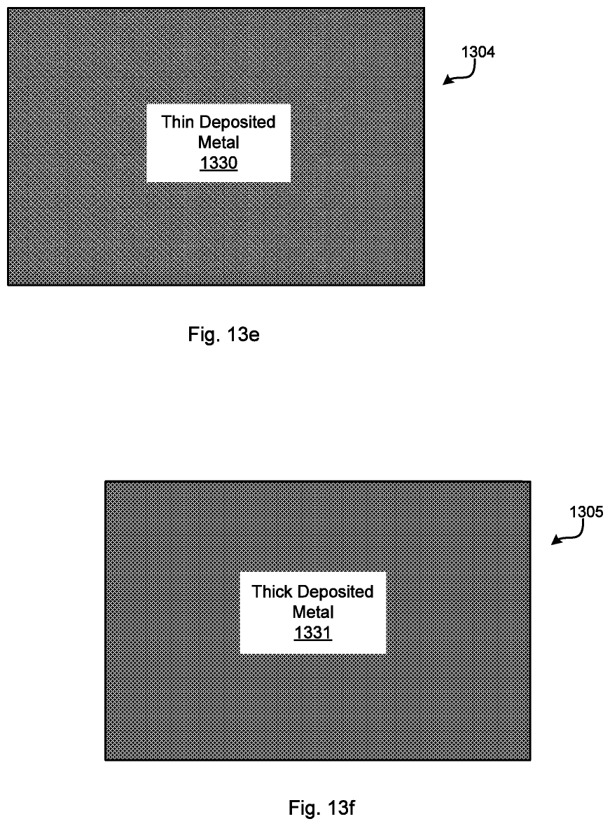

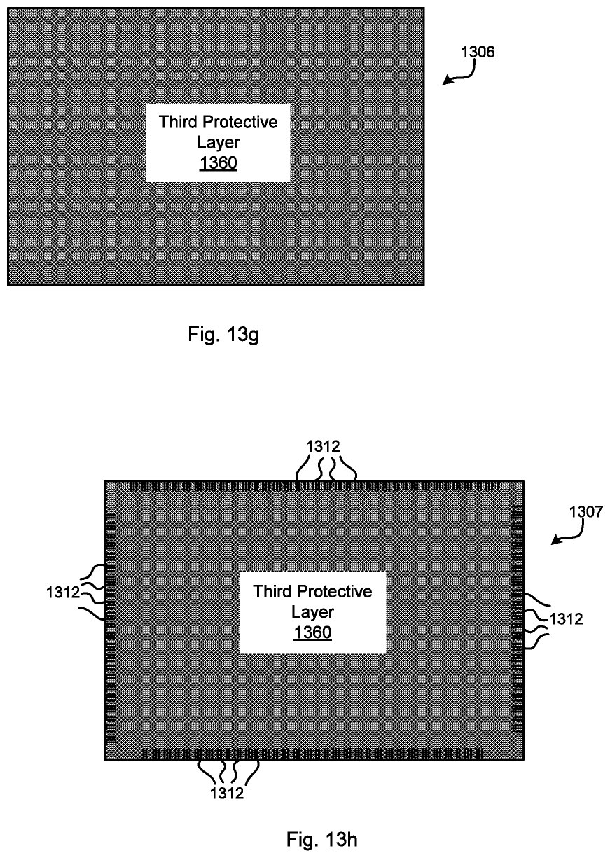

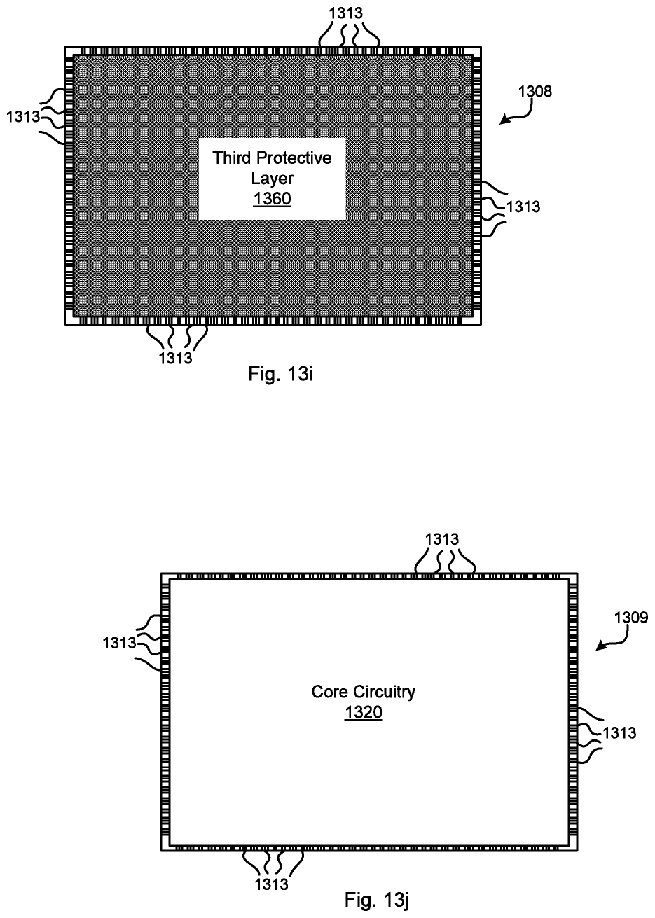

The core circuitry may include, but is not limited to, column driver circuits, row driver circuits, light emitting diodes, and conductive interconnect formed or placed in a central region of one or both of a top surface and a bottom surface of the substrate. In some cases, thin film transistor technology is used to form at least a part of the core circuitry. Based upon the disclosure provided herein, one of ordinary skill in the art will recognize a variety of circuitry and/or interconnect that may be incorporated into the core circuitry. The surface electrode portion of various wrap-around, edge electrodes are formed around a periphery of the substrate and extend from contact locations within the core circuitry to the edge of the substrate. Turning to FIG. 13a, an example of a display tile 1300 having a substrate including core circuitry 1320 in a central region and surface electrode portions 1310 of wrap-around edge electrodes around a periphery of the substrate is shown.

Returning to FIG. 12, a first protective layer is formed on an outer perimeter of the display substrate to protect the surface electrode portions (block 1204). The first protective layer may be made of any material capable of protecting surface electrode portions during various processes including eventual removal of the material to expose the surface electrode portions. Further, application of the material of the first protective material may be done using any suitable application process known in the art. In some embodiments, a polyimide (PI) tape is applied around the perimeter of the substrate to protect the surface electrode portions. In other embodiments, a combination of one or more of PI, polyurethane (PU), and/or cyclic olefin copolymers are applied around the perimeter of the substrate to protect the surface electrode portions. Based upon the disclosure provided herein, one of ordinary skill in the art will recognize a variety of materials and application processes that may be used to form the first protective layer in accordance with different embodiments. Turning to FIG. 13b, an example of a display tile 1301 having a substrate including core circuitry 1320 in a central region and surface electrode portions (not shown) covered by a first protective layer 1311 is shown.

Returning to FIG. 12, a second protective layer is formed over the core structure of the substrate to protect core circuitry, interconnect, and other structure during processing (block 1206). The second protective layer may be made of any material capable of protecting the core structure during various processes including eventual removal of the first protective layer and the material of the second protective layer. Further, application of the material of the second protective material may be done using any suitable application process known in the art. In some embodiments, a standard thin film transistor protection material is deposited over the core structure. Based upon the disclosure provided herein, one of ordinary skill in the art will recognize a variety of materials and application processes that may be used to form the second protective layer in accordance with different embodiments. Turning to FIG. 13c, an example of a display tile 1302 having a substrate with core circuitry (not shown) covered by a second protective layer 1321 is shown. It should be noted that in some embodiments the second protective layer covers both the core structure and at least part of the first protective layer.

Returning to FIG. 12, the first protective layer is removed leaving the surface electrode portions exposed (block 1208). This is done by exposing the display substrate with a chemical and/or mechanical process that removes the first protective layer while leaving the second protective layer over the core structure. Where, for example, the first protective layer is PI tape, removal of the first protective layer is done by peeling the PI tape away from the display tile. In cases where the second protective layer at least partially covered the first protective layer, removal of the first protective layer removes any portion of the second protective layer disposed over the first protective layer. Turning to FIG. 13d, an example of a display tile 1303 having a substrate with core circuitry (not shown) covered by the second protective layer 1321 and the surface electrode portions 1310 exposed is shown.

Returning to FIG. 12, metal is deposited over all surfaces of the display tile to yield a thin metal coating (i.e., less than or equal to two micrometers (2 μm) in thickness) (block 1210). Any process for depositing metal may be used. In some embodiments, the metal deposition includes sputtering pure copper (Cu), silver (Ag), gold (Au), nickel (Ni), or their combinations. In other cases, the pure metal is a dual layer structure, such as Ti/Cu, TiW/Cu, TiN/Cu, Cr/Cu, where Ti, TiW, TiN or Cr is adhesion layer between pure metal and substrate. Based upon the disclosure provided herein, one of ordinary skill in the art will recognize a variety of metals or other conductive materials that may be used in relation to different embodiments, and/or a variety of processes that may be used to cover the display tile with the selected metal or other conductive material. Turning to FIG. 13e, an example of a display tile 1304 having a substrate with core circuitry (not shown) surface electrode portions (not shown) that are covered by a deposited metal 1330 is shown. The deposited metal 1330 covers all sides of the display tile.

Returning to FIG. 12, either electroplating or electroless plating is applied to cover the entire surface of the display substrate with a thick metal layer (i.e., greater than or equal to two micrometers (2 μm) in thickness) (block 1212). Turning to FIG. 13f, an example of a display tile 1305 having a substrate with core circuitry (not shown) surface electrode portions (not shown) that are covered by a plated metal 1331 is shown. The plated metal 1331 covers all sides of the display tile.

Returning to FIG. 12, a third protective layer is formed over the entire surface of the display substrate (block 1214). In some embodiments, the material of the third protective layer is an organic material exhibiting high etching resistance during etching process. Turning to FIG. 13g, an example of a display tile 1305 having a substrate with core circuitry (not shown) surface electrode portions (not shown) that are covered by a third protective layer 1360 is shown. The third protective layer 1360 covers all sides of the display tile.

Returning to FIG. 12, laser removal of a portion of the third protective layer is performed to define locations of wrap-around, edge electrodes around the perimeter of the display substrate (block 1216). Such laser removal is done along the periphery of the display tile and includes removal of all of the third protective layer from areas extending from a first surface of the display device across the edge of the display device to a second surface of the display device where a wrap-around electrode is not desired. In some embodiments, this process of laser removal is done by mounting the display tile in relation to a laser energy source such that the display tile can be moved relative to the laser energy source in three dimensions. Application of the laser energy to the metal ablates the material of the third protective layer. Turning to FIG. 13h, an example of a display tile 1307 is shown that has a substrate with core circuitry (not shown) covered by the third protective layer 1360 and exposed portions 1312 of the thick deposited metal 1331 where wrap-around, edge electrodes are not desired.

A wet etch is applied to the display tile to remove all metal exposed by the laser removal of the third protective layer (block 1218). For copper etching, acetic acid, or mixed phosphoric acid (HPO₃) with hydrogen peroxide (H₂O₂) or mixed sulfuric acid (H₂SO₄) with hydrogen peroxide (H₂O₂) or mixed FeCl₃ with HCl is applied. For titanium etching, buffer oxide etching (BOE), or diluted HF, or mixed hydrogen peroxide, sodium hydrogen phosphate and sodium fluorosilicate is used. This etching leaves thick wrap-around, edge electrodes defined around the perimeter of the display tile. Turning to FIG. 13i, an example of a display tile 1308 is shown that has a substrate with core circuitry (not shown) covered by the third protective layer 1360 and thick wrap-around, edge electrodes 1313 defined around the perimeter of the display tile. Returning to FIG. 12, the third protective layer and the second protective layer are removed (block 1220). Where the second and third protective layers are polymer layers, a solvent such as, for example, alcohol, acetone, or water with or without ultrasonication can be used. Turning to FIG. 13j, an example of a display tile 1309 is shown that has a substrate with core circuitry 1320 and thick wrap-around, edge electrodes 1313 defined around the perimeter of the display tile.

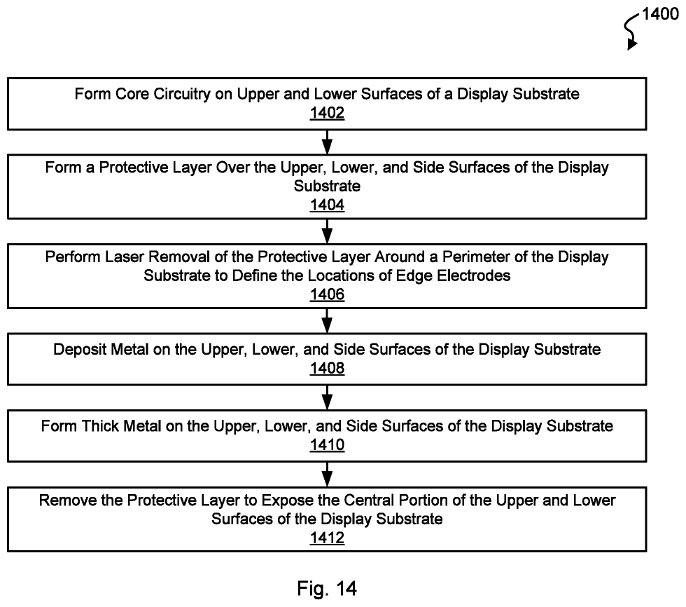

Turning to FIG. 14, a flow diagram 1400 shows a method in accordance with some embodiments for forming wrap-around, edge electrodes using a laser removal process. Following flow diagram 1400, core circuitry is formed on upper and/or lower surfaces of a display substrate (block 1402). The core circuitry may be formed using any suitable technology known in the art.

The display substrate may be made of any suitable material, for example, a polymeric substrate, printed circuit board, metal, glass-based, ceramic, sapphire, or silicon substrate having any desired size and/or shape appropriate to produce a display tile. In some embodiments, the substrate may be, but is not limited to, a rectangular, square, or rhomboid sheet having four edges, although other shapes and configurations are intended to fall within the scope of the disclosure including those having one or more curvilinear portions or edges. In various embodiments, the substrate may have a thickness d1 of less than or equal to about 3 mm. In some embodiments, the thickness of the substrate is between 0.01 mm and three (3) mm. In some embodiments, the substrate thickness is between 0.1 mm and 2.5 mm. In various embodiments, the substrate thickness is between 0.3 mm and two (2) mm. In some embodiments, the substrate thickness is between 0.3 mm and 1.5 mm. In some embodiments, the substrate thickness between 0.3 mm and one (1) mm. In some embodiments, the substrate thickness is between 0.3 mm and 0.7 mm. In various embodiments, the substrate thickness is between 0.3 mm and 0.5 mm.

In some embodiments, the substrate is a glass-based substrate. For example, such a glass-based substrate may comprise aluminosilicate, alkali-aluminosilicate, borosilicate, alkali-borosilicate, aluminoborosilicate, alkali-aluminoborosilicate, soda lime, or other suitable glasses. Non-limiting examples of commercially available glasses suitable for use as a glass substrate include, for example, EAGLE XG®, Lotus™, Willow®, and Astra™ glasses from Corning Incorporated.

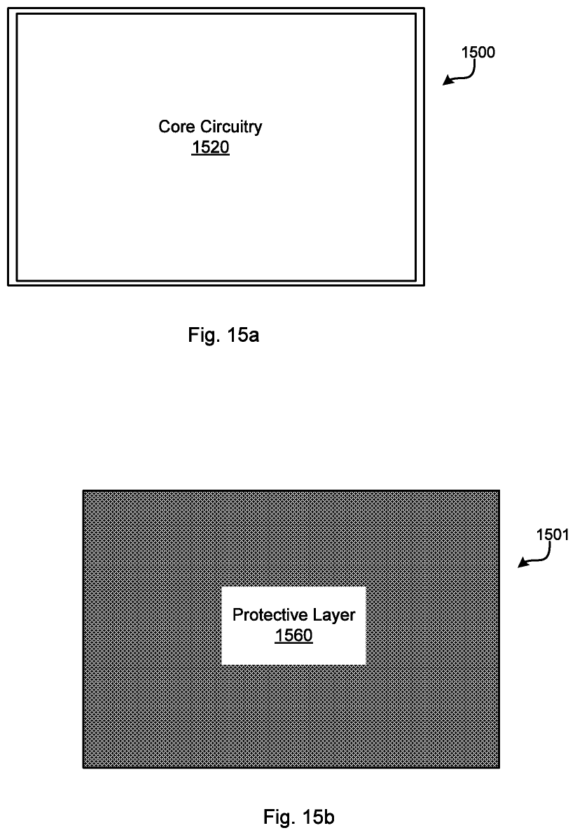

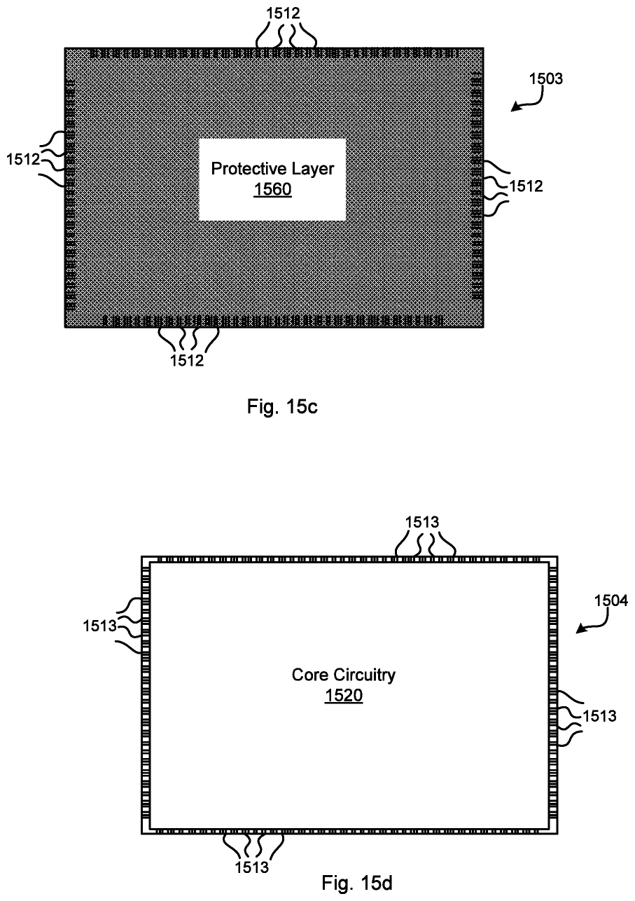

The core circuitry may include, but is not limited to, column driver circuits, row driver circuits, light emitting diodes, and conductive interconnect formed or placed in a central region of one or both of a top surface and a bottom surface of the substrate. In some cases, thin film transistor technology is used to form at least a part of the core circuitry. Based upon the disclosure provided herein, one of ordinary skill in the art will recognize a variety of circuitry and/or interconnect that may be incorporated into the core circuitry. The surface electrode portion of various wrap-around, edge electrodes are formed around a periphery of the substrate and extend from contact locations within the core circuitry to the edge of the substrate. Turning to FIG. 15a, an example of a display tile 1500 having a substrate including core circuitry 1520 in a central region and surface electrode portions 1510 of wrap-around edge electrodes around a periphery of the substrate is shown.

Returning to FIG. 14, a protective layer is formed over all surfaces of the display substrate (block 1404). Turning to FIG. 15b, an example is shown of a display tile 1501 having a substrate including core circuitry (not shown) in a central region with a protective layer 1560 formed over all surfaces of the display tile.

Returning to FIG. 14, laser removal of a portion of the protective layer is performed to define locations of wrap-around, edge electrodes around the perimeter of the display substrate (block 1406). Where electroplating is to be used in later processes, this laser removal leaves a metal trace that extends approximately perpendicular to the defined wrap-around, edge electrodes resulting in an electrical connection between the wrap-around, edge electrodes. Such laser removal is done along the periphery of the display tile and includes removal of all of the third protective layer from areas extending from a first surface of the display device across the edge of the display device to a second surface of the display device where a wrap-around electrode is not desired. In some embodiments, this process of laser removal is done by mounting the display tile in relation to a laser energy source such that the display tile can be moved relative to the laser energy source in three dimensions. Application of the laser energy to the metal ablates the material of the third protective layer. Turning to FIG. 15c, an example of a display tile 1502 is shown that has a substrate with core circuitry (not shown) covered by the protective layer 1560 and exposed portions 1512 where wrap-around, edge electrodes are desired.

Returning to FIG. 14, metal is deposited over all surfaces of the display tile to yield a thin metal coating (i.e., less than or equal to two micrometers (2 μm) in thickness) (block 1408). Any process for depositing metal may be used. In some embodiments, the metal deposition includes sputtering pure copper (Cu), silver (Ag), gold (Au), nickel (Ni), or their combinations. In other cases, the pure metal is a dual layer structure, such as Ti/Cu, TiW/Cu, TiN/Cu, Cr/Cu, where Ti, TiW, TiN or Cr is adhesion layer between pure metal and substrate. Based upon the disclosure provided herein, one of ordinary skill in the art will recognize a variety of metals or other conductive materials that may be used in relation to different embodiments, and/or a variety of processes that may be used to cover the display tile with the selected metal or other conductive material. Later, either electroplating or electroless plating is applied to cover the entire surface of the display substrate with a thick metal layer (i.e., greater than or equal to two micrometers (2 μm) in thickness) (block 1410). Where the metal trace was included for use in electroplating, it is removed by laser ablation.

Returning to FIG. 14, the third protective layer is removed (block 1412). Where the protective layer is a polymer layer, a solvent such as, for example, alcohol and acetone with or without ultrasonication can be used. Turning to FIG. 15c, an example of a display tile 1509 is shown that has a substrate with core circuitry 1520 and thick wrap-around, edge electrodes 1513 defined around the perimeter of the display tile.

In conclusion, various novel systems, devices, methods and arrangements for edge electrodes. While detailed descriptions of one or more embodiments have been given above, various alternatives, modifications, and equivalents will be apparent to those skilled in the art without varying from the spirit of the disclosure. Therefore, the above description should not be taken as limiting the scope of the disclosure, which is defined by the appended claims.

What is claimed is:

1. A display tile, the display tile comprising:
a substrate including: a first surface and a second surface, and a side extending between the first surface and the second surface along a portion of an outer perimeter of the substrate; and
an electrode extending from a first contact location on the first surface of the substrate around the side to a second contact location on the second surface, wherein a cross-sectional width of the electrode measured perpendicular to the electrode and parallel to the first surface is less than or equal to two hundred micrometers, and a minimum thickness of the electrode measured perpendicular to the first surface from the first surface to an opposite surface of the electrode is greater than or equal to two hundred nanometers.

2. The display tile of claim 1, the display tile further comprising:
a circuit disposed on or near the second surface;
an electrical element disposed on or near the first surface; and
wherein the electrode electrically connects the circuit with the electrical element.

3. The display tile of claim 2, wherein the circuit is a row driver, and wherein the electrical element is a pixel element.

4. The display tile of claim 3, wherein the pixel element is selected from a group consisting of: an LED, a microLED, an LCD display element, an OLED display element, a CMOS element, and a transistor element.

5. The display tile of claim 1, wherein the minimum thickness of the electrode measured perpendicular to the first surface from the first surface to the opposite surface of the electrode is greater than or equal to five micrometers.

6. The display tile of claim 1, wherein the minimum thickness of the electrode measured perpendicular to the first surface from the first surface to the opposite surface of the electrode is greater than or equal to eight micrometers.

7. The display tile of claim 1, wherein the substrate is a glass-based substrate.

8. The display tile of claim 1, wherein a thickness of the side measured as a distance along a line perpendicular to the first surface and extending between the first surface and the second surface is less than or equal to three (3) millimeters.

9. The display tile of claim 1, wherein the electrode is formed of metal that is greater than ninety-eight percent pure.

10. The display tile of claim 1, wherein the pure metal is selected from a group consisting of: copper (Cu), silver (Ag), gold (Au), nickel (Ni), or any combination of copper (Cu), silver (Ag), gold (Au), nickel (Ni).

11. A method of manufacturing a multi-substrate device, the method comprising:
depositing a conductive material over at least a first surface of a substrate, a second surface of the substrate, and a side surface of the substrate extending between the first surface and the second surface along a portion of an outer perimeter of the substrate; and
laser removing a portion of the conductive material extending from the first surface of the substrate around the side to the second surface leaving a plurality of electrodes formed of the conductive material electrically connecting a first contact location on the first surface to a second contact location on the second surface.

12. The method of claim 11, wherein a cross-sectional width of the electrode measured perpendicular to the electrode and parallel to the first surface is less than or equal to two hundred micrometers, and a minimum thickness of the electrode measured perpendicular to the first surface from the first surface to an opposite surface of the electrode is less than or equal to two micrometers.

13. The method of claim 11, the method further comprising:
forming a circuit on or near the second surface;
connecting an electrical element on or near the first surface; and
wherein the electrode electrically connects the circuit with the electrical element.

14. The method of claim 13, wherein the circuit is a row driver, and wherein the electrical element is a pixel element.

15. The method of claim 13, wherein the pixel element is selected from a group consisting of: an LED, a microLED, an LCD display element, an OLED display element, a CMOS element, and a transistor element.

16. The method of claim 11, the method further comprising:
plating the electrode with a plating material such that the minimum thickness of the electrode measured perpendicular to the first surface from the first surface to the opposite surface of the electrode is greater than or equal to three micrometers.

17. The method of claim 16, wherein the plating is done using a plating process selected from a group consisting of: electroplating, and electroless plating.

18. The method of claim 16, wherein the minimum thickness of the electrode measured perpendicular to the first surface from the first surface to the opposite surface of the electrode is greater than or equal to five micrometers.

19. The method of claim 16, wherein the minimum thickness of the electrode measured perpendicular to the first surface from the first surface to the opposite surface of the electrode is greater than or equal to eight micrometers.

20. The method of claim 16, wherein the substrate is a glass-based substrate.

21. The method of claim 16, wherein the plating material is pure metal.

22. The method of claim 16, wherein the pure metal is selected from a group consisting of: copper (Cu), silver (Ag), gold (Au), nickel (Ni), or any combination of copper (Cu), silver (Ag), gold (Au), nickel (Ni).

23. A method of manufacturing a multi-substrate device, the method comprising:
forming a conductive material over at least a part of a first surface of a substrate, a second surface of the substrate, and a side surface of the substrate extending between the first surface and the second surface along a portion of an outer perimeter of the substrate;
forming a protective layer over at least part of each of the first surface, the second surface, and the side;
laser removing a portion of the protective layer corresponding to open area between a plurality of electrodes; and
etching to remove the conductive material from the area exposed by the laser removing to leave the plurality of electrodes, wherein each of the plurality of electrodes extends from a first contact location on the first surface of the substrate around the side to a second contact location on the second surface.

24. The method of claim 23, wherein forming the conductive material over at least the part of the first surface of a substrate, the second surface of the substrate, and the side surface of the substrate includes a combination of metal sputtering and metal plating.

25. The method of claim 24, wherein the metal plating is selected from a group consisting of: electroplating, and electroless plating.

26. A method of manufacturing a multi-substrate device, the method comprising:
forming a protective layer over at least a part of a first surface of a substrate, a second surface of the substrate, and a side surface of the substrate extending between the first surface and the second surface along a portion of an outer perimeter of the substrate;
laser removing a portion of the protective layer corresponding to open area between a plurality of electrodes;
forming a conductive material over at least a subset of the part of the first surface of the substrate, the second surface of the substrate, and the side surface of the substrate; and
removing the protective to leave a plurality of electrodes formed of the conductive material, wherein each of the plurality of electrodes extends from a first contact location on the first surface of the substrate around the side to a second contact location on the second surface.

27. The method of claim 26, wherein forming the conductive material over at least the subset of the part of the first surface of a substrate, the second surface of the substrate, and the side surface of the substrate includes a combination of metal sputtering and metal plating.

28. The method of claim 27, wherein the metal plating is selected from a group consisting of: electroplating, and electroless plating.
